(19) United States
(12) Patent Application Publication
(10) Pub. No.: US 2024/0022079 A1
(43) Pub. Date: Jan. 18, 2024

(54) HYBRID ELECTRICAL POWER GENERATION SYSTEM AND METHOD OF SIMULATING THE SAME

(71) Applicant: Vast Solar Pty Ltd, Darlinghurst, New South Wales (AU)

(72) Inventors: Brian William MENZIES, Darlinghurst, New South Wales (AU); Luke Alexander Arthur HARDIMAN, Darlinghurst, New South Wales (AU)

(21) Appl. No.: 18/032,150

(22) PCT Filed: Oct. 18, 2021
(86) PCT No.: PCT/AU2021/051213

§ 371 Date: Apr. 14, 2023

(30) Foreign Application Priority Data
Oct. 16, 2020 (AU) 2020903758

(51) Int. Cl. H02J 3/38; H02J 3/46; H02J 3/00; H02J 3/32

(52) U.S. Cl. CPC H02J 3/381; H02J 3/466; H02J 3/003; H02J 3/004; H02J 3/32; H02J 2300/24; H02J 2300/40; H02J 2300/10

(57) ABSTRACT

A method of operating a hybrid electrical power generation system (100) to supply an electrical demand, the hybrid electrical power generation system (100) having a battery energy storage system (BESS) (170), a renewable energy RE power plant (120), and a combustion power plant (160) having a supply delay, the supply delay being a time associated with signalling the combustion power plant (160) to start-up to the combustion power plant (160) being capable of supplying the electrical demand, the method comprising: determining a state of charge of the BESS (170); in response to determining that the RE power plant (120) is generating electrical power and the state of charge of the BESS (170) is at least at a secure level (176) capable of supplying the electrical demand during the supply delay: dispatching the RE power plant (120) to supply at least some of the electrical demand: and in response to determining that the RE power plant (120) is generating electrical power and the state of charge of the BESS (170) is at an insecure level that is incapable of supplying the electrical demand during the supply delay: dispatching the RE power plant (120) to charge the BESS (170).

### FIELD OF THE INVENTION

The present disclosure is directed to a hybrid electrical power generation system and a method of simulating the same.

### BACKGROUND OF THE INVENTION

Hybrid electrical power generation systems that utilise different generation technologies to supply an electrical demand to an electrical load are known. For example, known hybrid electrical power generation systems may utilise one or more intermittent power generation technologies (i.e. variable renewable energy (VRE) power generators such as photovoltaic power plants and wind turbines) and one or more traditional power generation technologies (e.g. gas turbines, gas engines, petrol engines, and diesel engines) to supply an electrical demand to an electrical load. Other contemplated hybrid electrical power generation systems may utilise one or more dispatchable renewable energy power generation technologies (e.g. pumped hydroelectric power, concentrating solar thermal power (CSP), etc.) instead of, or in addition to, the intermittent power generation technologies. However, these known and contemplated hybrid electrical power generation systems may not be able to supply the electrical demand if the electrical power generated by the one or more intermittent (VRE) and/or dispatchable renewable energy power generation technologies is unable to fully supply the electrical demand and the one or more traditional generation technologies are unavailable to cover the shortfall.

Reference to any prior art in the specification is not an acknowledgment or suggestion that this prior art forms part of the common general knowledge in any jurisdiction or that this prior art could reasonably be expected to be understood, regarded as relevant, and/or combined with other pieces of prior art by a skilled person in the art.

### SUMMARY OF THE INVENTION

In a first aspect, the present invention provides a method of operating a hybrid electrical power generation system to supply an electrical demand, the hybrid electrical power generation system having a battery energy storage system (BESS), a renewable energy (RE) power plant, and a combustion power plant having a supply delay, the supply delay being a time associated with signalling the combustion power plant to start-up to the combustion power plant being capable of supplying the electrical demand, the method comprising: determining a state of charge of the BESS; in response to determining that the RE power plant is generating electrical power and the state of charge of the BESS is at least at a secure level capable of supplying the electrical demand during the supply delay: dispatching the RE power plant to supply at least some of the electrical demand; and in response to determining that the RE power plant is generating electrical power and the state of charge of the BESS is at an insecure level that is incapable of supplying the electrical demand during the supply delay: dispatching the RE power plant to charge the BESS.

In an embodiment, the RE power plant comprises a variable renewable energy (VRE) power plant

In an embodiment, the method further comprises: in response to determining that the VRE power plant is generating electrical power and the state of charge of the BESS is at least at the secure level: dispatching the VRE power plant to supply the electrical demand if the electrical power generated by the VRE power plant is capable of supplying the electrical demand; or dispatching the BESS to supply at least some of the electrical demand and dispatching the VRE power plant to supply at least some of the electrical demand if the electrical power generated by the VRE power plant is incapable of supplying the electrical demand and the combustion generator is not operating.

In an embodiment, the method further comprises starting the combustion power plant in response to determining that the VRE power plant is generating electrical power, the state of charge of the BESS is at the insecure level, and the combustion power plant is not operating.

In an embodiment, the method further comprises, in response to determining that the VRE power plant is generating electrical power, the state of charge of the BESS is at least at the secure level, and the electrical power generated by the VRE power plant is in excess of the electrical demand: dispatching the VRE power plant to supply the electrical demand; and charging the BESS with the excess electrical power generated by the VRE power plant.

In an embodiment, the method further comprises, in response to determining that the VRE power plant is generating electrical power, the state of charge of the BESS is at the insecure level, and the combustion generator is operating: dispatching the combustion generator to supply the electrical demand; and charging the BESS with the electrical power generated by the VRE power plant.

In an embodiment, the VRE power plant comprises at least one photovoltaic (PV) power plant and/or at least one wind turbine power plant.

In an embodiment, the hybrid electrical power generation system further comprises a concentrating solar thermal power (CSP) plant and the method further comprises, in response to determining that the VRE power plant is generating electrical power and the state of charge of the BESS is at least at the secure level: dispatching the BESS to supply at least some of the electrical demand and dispatching the VRE power plant to supply at least some of the electrical demand if the electrical power generated by the VRE power plant is incapable of supplying the electrical demand and the CSP plant and the combustion generator are not operating.

In an embodiment, the method further comprising, in response to determining that the VRE power plant is generating electrical power and the state of charge of the BESS is at least at the secure level: dispatching the combustion generator to supply at least some of the electrical demand and dispatching the VRE power plant to supply at least some of the electrical demand if the electrical power generated by the VRE power plant is incapable of supplying the electrical demand and the combustion generator is operating.

In an embodiment, the method further comprises, in response to determining that the VRE power plant is generating electrical power and the state of charge of the BESS is at least at the secure level: dispatching the CSP plant to supply at least some of the electrical demand and dispatching the VRE power plant to supply at least some of the electrical demand if the electrical power generated by the VRE power plant is incapable of supplying the electrical demand and the CSP plant is operating.

In an embodiment, the RE power plant comprises a concentrating solar thermal power (CSP) plant

In an embodiment, the method further comprises, in response to determining that the CSP plant is not operating, the state of charge of the BESS is at the insecure level and the CSP plant has received instructions to start-up: charging the BESS with the electrical power generated by at least one power plant of the hybrid electrical power generation system; and deferring dispatch of the CSP plant to supply at least some of the electrical demand until the state of charge of the BESS is at the secure level

In a second aspect, the present invention provides a hybrid electrical power generation system for supplying an electrical demand, the electrical power generation system comprising: a renewable energy (RE) power plant; a combustion generator having a supply delay, the supply delay being a time associated with signalling the combustion power plant to start-up to the combustion power plant being capable of supplying the electrical demand; a battery energy storage system (BESS); and a controller configured to dispatch the RE power plant, the combustion generator, and the BESS to supply the electrical demand, wherein, in response to determining that the RE power plant is generating electrical power and the state of charge of the BESS is at least at a secure level capable of supplying the electrical demand during the supply delay, the controller is configured to: dispatch the RE power plant to supply at least some of the electrical demand; and in response to determining that the RE power plant is generating electrical power and the state of charge of the BESS is at an insecure level that is incapable of supplying the electrical demand during the supply delay, the controller is configured to: dispatch the RE power plant to charge the BESS.

In an embodiment, the RE power plant comprises a variable renewable energy (VRE) power plant.

In an embodiment, the controller is configured to carry out one or more methods of the first aspect.

In an embodiment, the VRE power plant comprises at least one photovoltaic (PV) power plant and/or at least one wind turbine power plant

In an embodiment, the hybrid electrical power generation system further comprises a concentrating solar thermal power (CSP) plant, wherein, in response to determining that the VRE power plant is generating electrical power and the state of charge of the BESS is at least at the secure level, the controller is configured to: dispatch the BESS to supply at least some of the electrical demand and dispatch the VRE power plant to supply at least some of the electrical demand if the electrical power generated by the VRE power plant is incapable of supplying the electrical demand and the CSP plant and the combustion generator are not operating.

In an embodiment, the RE power plant comprises a concentrating solar thermal power (CSP) plant.

In an embodiments, in response to determining that the CSP plant is not operating, the state of charge of the BESS is at the insecure level and the CSP plant has received instructions to start-up, the controller is configured to: charge the BESS with the electrical power generated by at least one power plant of the hybrid electrical power generation system; and defer dispatch of the CSP plant to supply at least some of the electrical demand until the state of charge of the BESS is at the secure level

In a third aspect, the present invention provides a method for operating a hybrid electrical power generation system to supply an electrical demand at a future time period, the hybrid electrical power generation system having a battery energy storage system (BESS), a renewable energy (RE) power plant, and a combustion power plant having a supply delay, the supply delay being a time associated with signalling the combustion power plant to start-up to the combustion power plant being capable of supplying the electrical demand, the method comprising: determining a potential electrical power generated by the RE power plant for the future time period using weather data; determining a potential state of charge of the BESS for the future time period; determining an operating status of the combustion power plant for the future time period in response to determining that, at the future time period, the potential electrical power generated by the RE power plant will be unable to meet the electrical demand and that the potential state of charge of the BESS will be at least at a secure level capable of supplying the electrical demand during the supply delay: scheduling the RE power plant to be dispatched at the future time period to supply at least some of the electrical demand; and in response to determining that, at the future time period, the RE power plant will be generating electrical power and that the potential state of charge of the BESS will be at an insecure level that will be incapable of supplying the electrical demand during the supply delay: scheduling the RE power plant to be dispatched at the future time period to charge the BESS.

In an embodiment, the RE power plant comprises a variable renewable energy (VRE) power plant

In an embodiment, the method further comprises, in response to determining that, at the future time period, the VRE power plant will be generating electrical power and that the potential state of charge of the BESS will be at least at the secure level: scheduling the VRE power plant to be dispatched at the future time period to supply the electrical demand if the potential electrical power generated by the VRE power plant will be capable of supplying the electrical demand; or scheduling the BESS to be dispatched for the future time period to supply at least some of the electrical demand and scheduling the VRE power plant to be dispatched at the future time period to supply at least some of the electrical demand if the potential electrical power generated by the VRE power plant will be incapable of supplying the electrical demand and the combustion generator will not be operating.

In an embodiment, the method further comprises scheduling the combustion power plant to start before the future time period in response to determining that, at the future time period, the VRE power plant will be generating electrical power and the potential state of charge of the BESS will be at the insecure level.

In an embodiment, the method further comprises, in response to determining that, at the future time period, the potential electrical power generated by the VRE power plant will be in excess of the electrical demand and the potential state of charge of the BESS will be at least at the secure level: scheduling the VRE power plant to be dispatched at the future time period to supply the electrical demand; and scheduling the BESS to be charged at the future time period with the excess electrical power generated by the VRE power plant.

In an embodiment, the method further comprises, in response to determining that, at the future time period, the VRE power plant will be generating electrical power, the potential state of charge of the BESS will be at the insecure level, and the combustion generator will be operating: scheduling the combustion generator to be dispatched at the future time period to supply the electrical demand; and scheduling the BESS to be charged at the future time period with the electrical power generated by the VRE power plant.

In an embodiment, the VRE power plant comprises at least one photovoltaic (PV) power plant and/or at least one wind turbine power plant.

In an embodiment, the electrical power generation system further comprises a concentrating solar power (CSP) plant and the method further comprises: determining the operating status of the concentrating power plant for the future time period using the weather data; and in response to determining that, at the future time period, the VRE power plant will be generating electrical power and the state of charge of the BESS will be at least at the secure level: scheduling the BESS to be dispatched at the future time period to supply at least some of the electrical demand and scheduling the VRE power plant to be dispatched at the future time period to supply at least some of the electrical demand if the potential electrical power generated by the VRE power plant will be incapable of supplying the electrical demand and the CSP plant and combustion generator are not operating for the future time period.

In an embodiment, the method further comprises, in response to determining that, at the future time period, the VRE power plant will be generating electrical power and the potential state of charge of the BESS will be at least at the secure level: scheduling the combustion generator to be dispatched at the future time period to supply at least some the electrical demand and scheduling the VRE power plant to be dispatched at the future time period to supply at least some of the electrical demand if the potential electrical power generated by the VRE power plant will be incapable of supplying the electrical demand and the combustion generator will be operating for the future time period.

In an embodiment, the method further comprises, in response to determining that, at the future time period, the VRE power plant will be generating electrical power and the potential state of charge of the BESS will be at least at the secure level: scheduling the CSP plant to be dispatched at the future time period to supply at least some of the electrical demand and scheduling the VRE power plant to be dispatched at the future time period to supply at least some of the electrical demand if the potential electrical power generated by the VRE power plant will be incapable of supplying the electrical demand and the CSP plant will be operating for the future time period.

In an embodiment, the RE power plant comprises a concentrating solar thermal power (CSP) plant.

In an embodiment, the method further comprises, in response to determining that, at the future time period, the CSP plant will not be operating, the state of charge of the BESS will be at the insecure level and the CSP plant will receive instructions to start-up: scheduling the BESS to be charged at the future time period with the electrical power generated by at least one power plant of the hybrid electrical power generation system; and deferring dispatch of the CSP plant to supply at least some of the electrical demand until the state of charge of the BESS will be at the secure level.

In an embodiment, the weather data is forecasted weather data for a location at which the hybrid electrical power generation system is installed.

In a fourth aspect, the present invention provides a hybrid electrical power generation system for supplying an electrical demand, the electrical power generation system comprising: a renewable energy (RE) power plant; a combustion generator having a supply delay, the supply delay being a time associated with signalling the combustion power plant to start-up to the combustion power plant being capable of supplying the electrical demand; a battery energy storage system (BESS); and a controller configured to: schedule dispatch of the RE power plant, the combustion generator, and the BESS to supply the electrical demand; and determine, for a future time period, the potential electrical power generated by the RE power plant using weather data, a potential state of charge of the BESS, and an operating status of the combustion power plant, wherein, in response to determining that, at the future time period, the potential electrical power generated by the RE power plant will be unable to meet the electrical demand and the potential state of charge of the BESS will be at least at a secure level capable of supplying the electrical demand during the supply delay, the controller is configured to: schedule the RE power plant to be dispatched at the future time period to supply at least some of the electrical demand; and in response to determining that, at the future time period, the RE power plant will be generating electrical power and the potential state of charge of the BESS will be at an insecure level that is incapable of supplying the electrical demand during the supply delay, the controller is configured to: schedule the VRE power plant to dispatched at the future time period to charge the BESS.

In an embodiment, the RE power plant comprises a variable renewable energy (VRE) power plant.

In an embodiment, the controller is configured to carry out one or more of the methods of the third aspect.

In an embodiment, the VRE power plant comprises at least one photovoltaic (PV) power plant and/or at least one wind turbine power plant.

In an embodiment, the hybrid electrical power generation system further comprises a concentrating solar power (CSP) plant, wherein: the controller is configured to determine the operating status of the CSP plant for the future time period using the weather data: and in response to determining that, at the future time period, the VRE power plant will be generating electrical power and the potential state of charge of the BESS will be at least at the secure level, the controller is configured to: schedule the BESS to be dispatched at the future time period to supply at least some of the electrical demand and schedule the VRE power plant to be dispatched at the future time period to supply at least some of the electrical demand if the potential electrical power generated by the VRE power plant will be incapable of supplying the electrical demand and the CSP plant and combustion generator are not operating for the future time period.

In an embodiment, the RE power plant comprises a concentrating solar thermal power (CSP) plant.

In an embodiment, in response to determining that, at the future time period, the CSP plant will not be operating, the state of charge of the BESS will be at the insecure level and the CSP plant will receive instructions to start-up, the controller is configured to: schedule the BESS to be charged at the future time period with the electrical power generated by at least one power plant of the hybrid electrical power generation system; and defer dispatch of the CSP plant to supply at least some of the electrical demand until the state of charge of the BESS is at the secure level.

In an embodiment, the weather data is forecasted weather data for a location at which the hybrid electrical power generation system is installed.

In a fifth aspect, the present invention provides a computer implemented method for simulating a hybrid electrical power generation system for supplying an electrical demand, the hybrid electrical power generation system having a battery energy storage system (BESS), a renewable energy RE power plant, and a combustion power plant having a supply delay, the supply delay being a time from signalling the combustion power plant to start-up to the combustion power plant being capable of supplying the electrical demand, the computer implemented method configured to perform the method of the third aspect.

In an embodiment, the weather data is historical weather data or representative weather data for a location at which the hybrid electrical power generation system is to be installed.

As used herein, except where the context requires otherwise, the term “comprise” and variations of the term, such as “comprising”, “comprises” and “comprised”, are not intended to exclude further additives, components, integers or steps.

### BRIEF DESCRIPTION OF THE DRAWINGS

Preferred embodiments of the present invention will be described, by way of examples only, with reference to the accompanying representations, wherein:

FIG. 1 is a schematic block diagram illustrating the components of a hybrid electrical power generation system according to an embodiment of the present invention;

FIG. 2 is a schematic block diagram of components of the concentrating solar power plant of FIG. 1;

FIG. 3 shows the different states of charge of the battery energy storage system of FIG. 1;

FIG. 4 is a schematic block diagram illustrating the components of a hybrid electrical power generation system according to another embodiment of the present invention;

FIG. 5 is a block diagram of a networked environment for simulating the hybrid electrical power generation system of FIG. 1 according to an embodiment of the present invention;

FIG. 6 is a block diagram of a computing system with which various embodiments of the present disclosure may be implemented;

FIG. 7 is a flowchart of a method for simulating the hybrid electrical power generator of FIG. 1 according to an embodiment of the present invention;

FIG. 8 is a flowchart for determining the operating status of the concentrating solar power plant of the hybrid electric power generation system of FIG. 1;

FIG. 9 is a flowchart for determining the operating status of the photovoltaic power plant of the hybrid electrical power generation system of FIG. 1;

FIG. 10 is a flowchart for determining the operating status of the combustion power plant of the hybrid electrical power generation system of FIG. 1;

FIG. 11 is a flowchart for determining the operating status of the battery energy storage system of the hybrid electrical power generation system of FIG. 1;

FIG. 12 is an example output generated from the simulation of the hybrid electrical power generation system of FIG. 1; and

FIG. 13 is another example output generated from the simulation of the hybrid electrical power generation system of FIG. 1.

### DETAILED DESCRIPTION OF THE EMBODIMENTS

### Hybrid Electrical Power Generation System

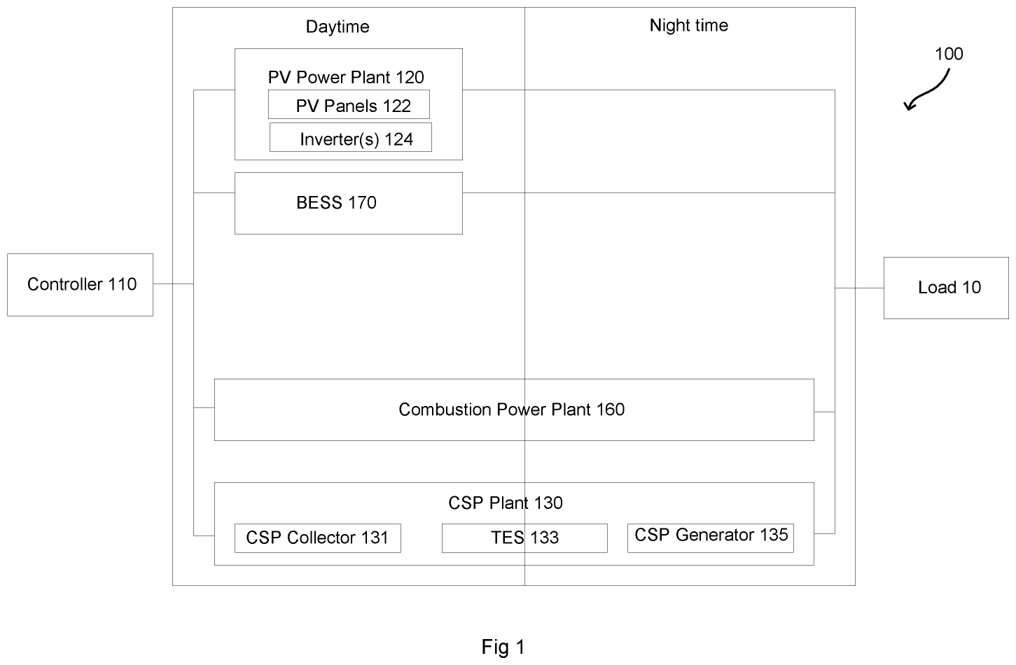

FIG. 1 is a schematic block diagram of an electrical power generation system 100 according to an embodiment of the present invention. The electrical power generation system 100 has a controller 110, a photovoltaic (PV) power plant 120, a concentrating solar thermal power (CSP) plant 130, a combustion power plant 160, and a battery energy storage system (BESS) 170. The controller 110 is configured to selectively dispatch the PV power plant 120, the CSP plant 130, the combustion power plant 160, and/or the BESS 170 in order to supply a given electrical demand to an electrical load 10. Each of the PV power plant 120, the CSP plant 130, the combustion power plant 160, and the BESS 170 have associated auxiliary electrical loads. These auxiliary electrical loads must also be met when supplying the electrical load 10 with the electrical demand. Accordingly, the hybrid electrical power generation system 100 must generate enough electrical power to meet the electrical demand and these auxiliary electrical loads.

The PV power plant 120 is electrically coupled to the electrical load 10 and the BESS 170. The controller 110 is configured to dispatch electrical power generated by the PV power plant 120 to the electrical load 10 and/or to the BESS 170 to charge the BESS 170.

Each of the CSP plant 130, the combustion power plant 160, and the BESS 170 are electrically coupled to the electrical load 10. The controller 110 is also configured to control each of the CSP plant 130, the combustion power plant 160, and the BESS 170 to supply electrical power to the electrical load 10.

The PV power plant 120 may comprise a plurality of PV or solar panels 122 and one or more inverters 124 to convert the direct current electrical power generated by the PV or solar panels 122 to alternating current electrical power. Each PV panel 122 may be configured to track the position of the sun in order to maximise the amount of electrical power generated by the PV power plant 120. Alternatively, each PV panel 122 may be stationary and disposed at an optimal angle in order to maximise the amount of electrical power generated by the PV power plant 120. Each PV panel 122 has PV operating data, for example, maximum power point (PMAX), maximum power point voltage (VMPP), maximum power point current (IMPP), open circuit voltage (Voc), short circuit current (Isc), nominal voltage (VNOM), and module efficiency (%). It will be appreciated that the above list of PV operating data is not exhaustive and that there are other PV operating data.

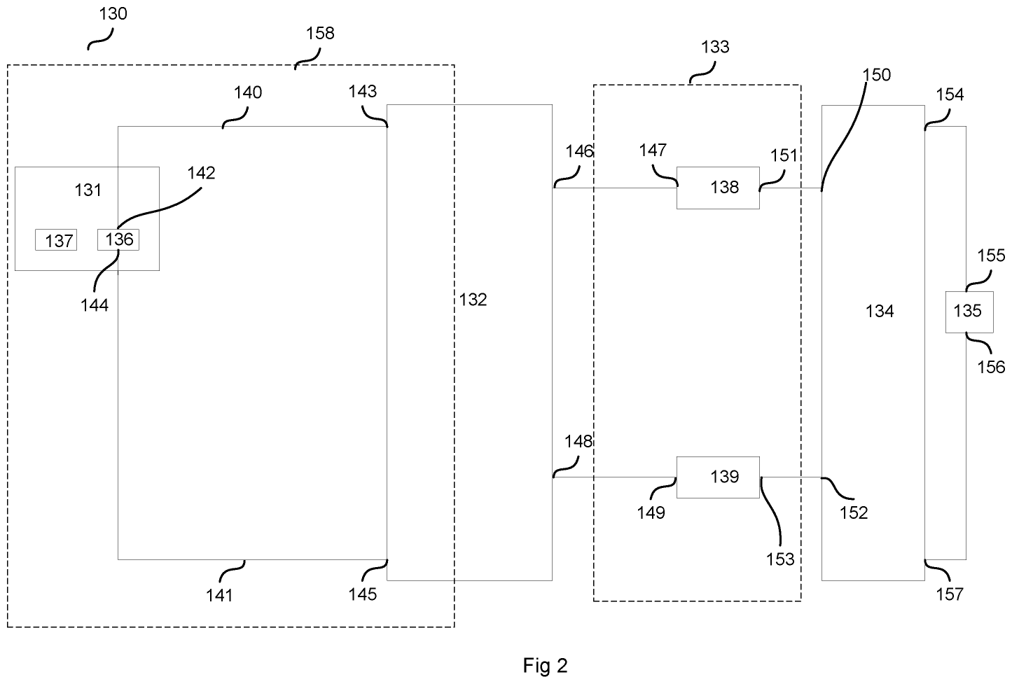

Referring to FIG. 2, the CSP plant 130 has a CSP collector 131, a storage tank heat exchanger 132, a thermal energy storage system (TESS) 133, a generator heat exchanger 134, and a CSP generator 135. The CSP collector 131 has a CSP receiver 136 and a CSP concentrator 137 configured to reflect and concentrate sunlight onto the CSP receiver 136. The TESS 133 has a hot energy storage tank 138 and a cold tank 139.

The CSP collector 131 may be any known type of CSP collector, for example, a dish CSP collector, a trough CSP collector, a tower CSP collector, or a Fresnel CSP collector.

If the CSP collector 131 is a dish CSP collector, the dish CSP collector will have a CSP concentrator 137 in the form of a dish and a CSP receiver 136 disposed at the focal point of the CSP concentrator 137. The CSP concentrator 137 may be configured to track to the position of the sun in order to reflect and concentrate sunlight onto the CSP receiver 136.

If the CSP collector 131 is a trough CSP collector, the trough CSP collector will have a CSP concentrator 137 in the form of a trough and a CSP receiver 136 disposed along the length, and at the focus of, the CSP collector 131. The CSP collector 131 may be configured to track the position of the sun in order to reflect and concentrate sunlight onto the CSP receiver 136.

If the CSP collector 131 is a tower CSP collector, the tower CSP collector will have a CSP concentrator 137 in the form of a plurality of heliostats and a CSP receiver 136 disposed on a tower. Each heliostat may be configured to track the position of the sun so that the heliostats reflect and concentrate sunlight onto the CSP receiver 136. The contents of international application no PCT/AU2020/050194 in the name of the Applicant titled “Method and system for controlling the operating of a CSP receiver” is incorporated herein by reference in its entirety.

If the CSP collector is a Fresnel CSP collector, the Fresnel CSP collector will have a CSP concentrator 137 in the form of a plurality of Fresnel concentrators and a CSP receiver 136 disposed along the length, and at the focus of, the plurality of Fresnel concentrators. Each Fresnel concentrator may be configured to track the position of the sun in order to reflect and concentrate sunlight onto the CSP receiver 136.

The CSP power plant 130 also comprises a hot heat transfer piping network 140 and a cold heat transfer piping network 141. The hot heat transfer piping network 140 couples an outlet 142 of the CSP receivers 136 in fluid communication with an inlet 143 of the storage tank heat exchanger 132. The cold heat transfer piping network 141 couples an inlet 144 of the CSP receivers 136 in fluid communication with an outlet 145 of the storage tank heat exchanger 132. The CSP collector 131, the hot heat transfer piping network 140, the cold heat transfer piping network 141, and the storage tank heat exchanger 132 define a heat transfer fluid (HTF) network 158 in which a CSP heat transfer medium (e.g. liquid sodium or thermal oil) may flow.

An outlet 146 of the storage tank heat exchanger 132 is in fluid communication with an inlet 147 of the hot energy storage tank 138 and an inlet 148 of the storage tank heat exchanger 132 is in fluid communication with an outlet 149 of the cold tank 139. An inlet 150 of the generator heat exchanger 134 is in fluid communication with an outlet 151 of the hot energy storage tank 138 and an outlet 152 of the generator heat exchanger 134 is in fluid communication with an inlet 153 of the cold tank 139. The storage tank heat exchanger 132, the hot energy storage tank 138, the cold thermal energy storage 139, and generator heat exchanger 134 define a heat transfer system in which a heat storage medium (e.g. salt) may flow.

An outlet 154 of the generator heat exchanger 134 is in fluid communication with an inlet 155 of the CSP generator 135 in order to deliver a heat transfer fluid (e.g. steam) heated by the generator heat exchanger 134 to the CSP generator 135 in order to drive the CSP generator 135. An outlet 156 of the CSP generator 135 is in fluid communication with an inlet 157 of the generator heat exchanger 134 in order to return the cooled heat transfer fluid (e.g. cooled steam) flowing out of the CSP generator 135 back to the generator heat exchanger 134 to be reheated by the generator heat exchanger 134. In an example, the CSP generator 135 is a steam turbine and the heat transfer fluid delivered from the generator heat exchanger 134 is steam.

In operation, the CSP concentrator 137 reflects and concentrates sunlight onto the CSP receiver 136, which heats the CSP heat transfer medium (e.g. liquid sodium) in the CSP receiver 136. The CSP heat transfer medium heated by the CSP receiver 136 flows out of the outlet 142 of the CSP receiver 136, through the hot heat transfer piping network 140, and into the storage tank heat exchanger 132 through the inlet 143. The heated CSP heat transfer medium flowing through the storage tank heat exchanger 132 exchanges heat with a portion of the heat storage medium (e.g. molten salt) flowing through the storage tank heat exchanger 132 from the cold tank 139. This causes the CSP heat transfer medium (e.g. sodium) flowing through the storage tank heat exchanger 132 to be cooled and the portion of the heat storage medium (salt) flowing through the storage tank heat exchanger 132 to be heated. The cooled CSP heat transfer medium flows out of the outlet 145 of the storage tank heat exchanger 132, through the cold heat transfer fluid piping network 141, and back into the CSP receiver 136 through the inlet 144 where it is heated again by the CSP receiver 136. The heated portion of the heat storage medium flows out of the outlet 146 of the storage tank heat exchanger 132 and into the hot energy storage tank 138 through the inlet 147, where it is stored.

When the CSP generator 135 is required to supply electrical power, a portion of the heat storage medium stored in the hot energy storage tank 138 flows out of the outlet 151 of the hot energy storage tank 138 and into the generator heat exchanger 134 through the inlet 150 and exchanges heat with a generator heat transfer medium (e.g. water/steam) flowing through the generator heat exchanger 134. This causes the heat storage medium flowing through the generator heat exchanger 134 to be cooled and the generator heat transfer medium flowing through the generator heat exchanger 134 to be heated. The cooled heat storage medium flows out of the outlet 152 of the generator heat exchanger 134 and back into the cold tank 139 through the inlet 153, where it may be heated again by the storage tank heat exchanger 132. The heated generator heat transfer medium flows out of the outlet 154 of the generator heat exchanger 134 to the CSP generator 135, which causes the CSP generator 135 to generate electrical power.

The CSP plant 130 has CSP operating data that include, for example, the maximum output (MW) of the CSP generator, the maximum storage of the hot energy storage tank 138, the minimum thermal energy to start CSP generator 135, the thermal energy shutdown level, the CSP minimum sun angle, CSP minimum offline period, the CSP maintenance period and date, the antifreeze temperature (K) of the heat storage medium, the temperature that the heat storage medium enters the hot energy storage tank 138, and the temperature that the heat storage medium enters the cold tank 139. It will be appreciated that the above list of CSP operating data is not exhaustive and that there are other CSP operating data.

The maximum storage of the hot energy storage tank 138 is the maximum of heat storage medium such as molten salt that can be stored in the hot energy storage tank 138. This is typically expressed in hours that the heat storage medium in the hot energy storage tank 138 can operate the CSP generator 135 at maximum output.

The minimum thermal energy to start the CSP generator 135 is the minimum amount of heat storage medium required to be in the hot energy storage tank 138 before the CSP generator 135 can be started. The amount of heat storage medium in the hot energy storage tank 138 determines how long the CSP generator 135 can be operated for. This is typically expressed in hours that the heat storage medium in the hot energy storage tank 138 can operate the CSP generator 135 at maximum output.

The thermal energy shutdown level is the amount of thermal energy in the hot energy storage tank 138 below which the CSP generator 135 must be shut down (i.e. taken offline) if no more energy is expected from the CSP collector 131.

The CSP minimum sun angle is the minimum angle that the sun must reach before starting the generator heat exchanger 134 and then the CSP generator 135. The CSP minimum sun angle may also require the sun to be descending in order to prevent the CSP generator 135 from generating electrical power in the morning as the sun rises. It will be appreciated that, in alternative embodiments, such restrictions on starting the generator heat exchanger 134 and then the CSP generator 135 may not be applied, or applied using different parameters, such as time of day, hours until civil twilight, PV plant output, electricity price, etc.

The CSP minimum offline period is the minimum amount of time that the CSP generator 135 must be offline before it can be started again. This may be defined by the original equipment manufacturer of the CSP generator 135.

The CSP maintenance period and date specifies the date and duration the CSP plant 130 will be unavailable due to maintenance.

Referring to FIG. 1, the combustion power plant 160 may be any known type of combustion generation system. For example, the combustion power plant 160 may be one or more gas turbines, one or more gas reciprocating combustion engines, one or more petrol reciprocating combustion engines, or one or more diesel reciprocating combustion engines.

The combustion power plant 160 has combustion power plant operating data, for example, the generating capacity of the combustion power plant 160, the start-up time of the combustion power plant 160, the ramp rate of the combustion power plant 160, the shutdown time of the combustion power plant 160, the combustion power plant minimum offline period, and the combustion power plant maintenance period and date.

The start-up time of the combustion power plant 160 is a period of time it takes from signalling the combustion power plant 160 to start-up to the combustion power plant 160 synchronizing with and supplying electrical power to the electrical grid (i.e. electrical load 10). This may be defined by the original equipment manufacturer of the combustion power plant 160.

The ramp-rate of the combustion power plant 160 is a measure of how quickly the electrical power output from the combustion power plant 160 can be increased or decreased to a given electrical output. This is typically expressed in units of power over time (e.g. MW per minute). This may be defined by the original equipment manufacturer of the combustion power plant 160.

The start-up time and the ramp rate of the combustion power plant 160 together define a supply delay for the combustion power plant 160. The supply delay is the time it takes from signalling the combustion power plant 160 to start-up to the time the combustion power plant 160 is capable of meeting the electrical demand. The supply delay is typically calculated based on the start-up time and the time it takes for the combustion power plant 160 to ramp-up to the electrical power demanded of it.

If the combustion power plant 160 comprises multiple combustion generators (e.g. turbines, reciprocating engines), one or more of these combustion generators may be dispatched to supply electrical power to the electrical load 10. If it is subsequently determined that only some of the dispatched combustion generators are required, one or more of the dispatched combustion generators may be taken offline. However, there is a minimum shutdown time that must be met before a combustion generator may be taken offline. The shutdown time of a combustion generator is typically a period of time it takes from signalling the combustion generator to shut down before it can be shutdown (i.e. taken offline and not operating). During the shutdown time, the combustion generator will be operating as a spinning reserve. The shutdown time may be defined by the designer of the hybrid electrical power generation system 100 so it will be appreciated that it may not correspond exactly to the defined shutdown time but may approximate it including a margin of error.

The combustion power plant minimum offline period is the minimum amount of time that the combustion power plant 160 must be offline before it can be started again. This may be defined by the original equipment manufacturer of the combustion power plant 160.

The combustion power plant maintenance period and date specifies the date and duration the combustion power plant 160 will be unavailable due to maintenance.

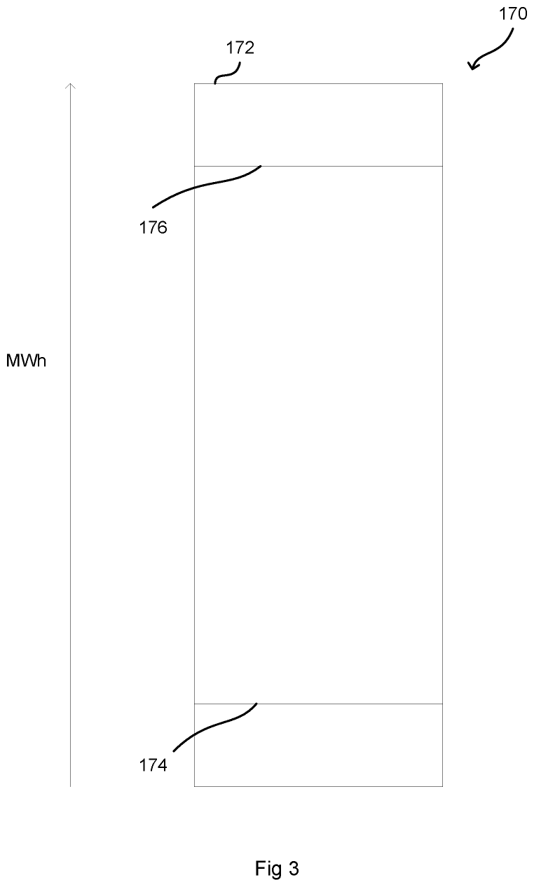

The BESS 170 may be any suitable battery system known in the art (e.g. lithium manganese oxide batteries and nickel-manganese cobalt batteries). FIG. 3 provides a representation of the different states of charge of the BESS 170. In particular, the BESS 170 has a maximum capacity 172, a maximum depth of discharge 174, and a battery system secure level 176. The maximum depth of discharge 174 is a state of charge of the BESS 170 at which the BESS 170 is considered discharged.

The BESS secure level 176 is a minimum state of charge of the BESS 170 that is capable of supplying at least a substantial portion of the given electrical demand during the supply delay of the combustion power plant 160. If the state of charge of the BESS 170 is equal to or greater than the BESS secure level 176, the BESS 170 is in a secure mode of operation. If the state of charge of the BESS 170 is less than the BESS secure level 176, the BESS 170 is in an insecure mode of operation.

The controller 110 dispatches the PV power plant 120, CSP plant 130, combustion power plant 160, and BESS 170 according to the following dispatch priority:
PV power plant 120—the PV power plant 120 is dispatched to supply electrical power to the electrical load 10 if the state of charge of the BESS 170 is at or above the secure level 176;
BESS 170—the BESS 170 is dispatched to supply electrical power to the electrical load 10 if the PV power plant 120 is operating but cannot supply the electrical demand to the electrical load 10 and the state of charge of the BESS 170 is at or greater than the secure level 176;
CSP plant 130—the CSP plant 130 is dispatched if it is determined that the CSP plant 130 is operating and the hot energy storage tank 138 has a sufficient volume of hot salt. In some embodiments, the CSP plant 130 may be dispatched only if it is also determined that the state of charge of the BESS 170 is at or above the secure level 176;
Combustion power plant 160—the combustion power plant 160 is dispatched to supply electrical power to the electrical load if the PV power plant 120 and the CSP plant 130 are unable to supply the electrical demand to the electrical load 10 and the state of charge of the BESS 170 is below the secure level 176; and
BESS 170—the BESS 170 is dispatched to supply electrical power to the electrical load 10 if the PV power plant 120, the CSP plant 130, and the combustion power plant 160 are unable to supply the electrical demand to the electrical load 10.

FIG. 1 also provides a conceptual view of the operation of the hybrid electrical power generation system 100. Broadly speaking, the operation of the hybrid electrical power generation system 100 is broken into a daytime operation and a night time operation.

Broadly, during the daytime operation, if there is enough sunlight, the PV power plant 120 will generate electrical power, which the controller 110 will dispatch to the electrical load 10 and/or to the BESS 170 if charging of the BESS 170 is required. The controller 110 is configured to dispatch the BESS 170 if the electrical power generated by the PV power plant 120 is not capable of supplying the electrical demand to the electrical load 10. If the PV power plant 120 and the BESS 170 are incapable of supplying the given electrical demand to the electrical load 10, the controller 110 is configured to dispatch the combustion power plant 160 to supply the given electrical demand to the electrical load.

Further, during the daytime operation, if there is enough sunlight, the CSP concentrator 137 reflects and concentrates sunlight onto the CSP receiver 136, which heats the CSP heat transfer medium. The heated CSP heat transfer medium heats a portion of the heat storage medium via the energy storage heat exchange 132, which is stored then stored in the hot energy storage tank 138.

Broadly, during the night time operation (i.e. when there is no sunlight), the hot heat storage medium stored in the hot tank 138 is passed through the generator heat exchanger 134 to produce a heated heat transfer fluid (e.g. steam) that is used to drive the CSP generator 135 (e.g. steam turbine) to generate electrical power, which the controller 110 dispatches to the electrical load 10.

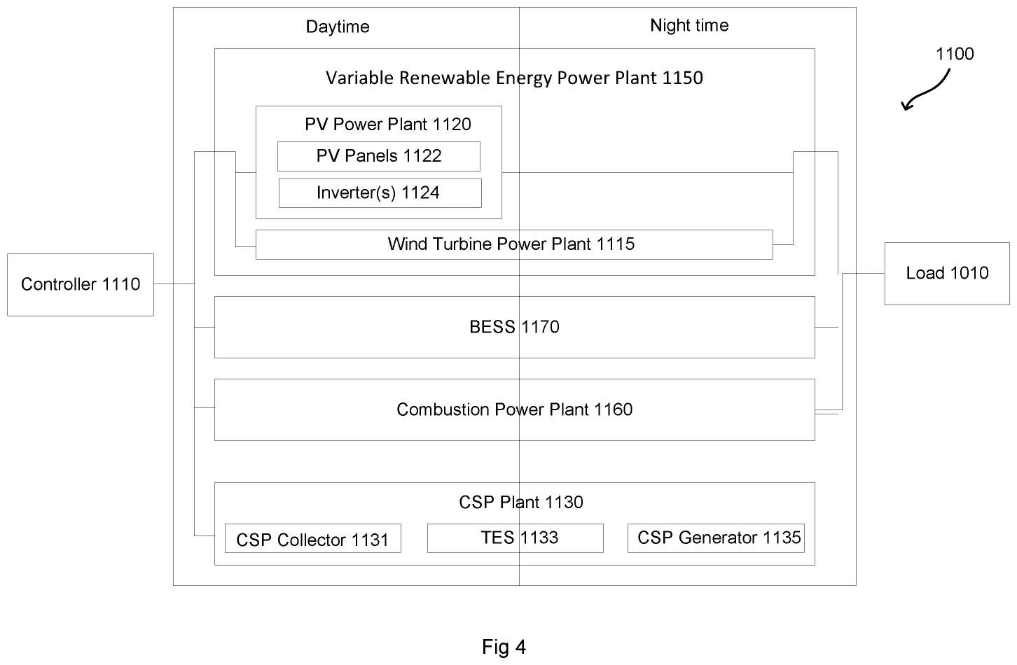

In the embodiment described above, the hybrid electrical power generation system 100 utilises two different renewable energy (RE) power generation technologies: a variable renewable energy (VRE) power plant (i.e. an intermittent power generation technology) in the form of the PV power plant 120; and a dispatchable RE power plant in the form of the CSP plant 130. It will be appreciated from the following description that the introduction of the BESS 170 allows alternative embodiments to utilise various combinations of differing RE power generation technologies with the combustion power plant 160. Each of these embodiments may comprise a controller configured to selectively dispatch the RE power plant/s, the combustion power plant, and/or the BESS in order to supply a given electrical demand to an electrical load. For example, in alternative embodiments, a hybrid electrical power generation system could utilise the combination of a BESS and combustion power plant with:
a single type VRE power plant—such as one or more PV power plants 120 as described above, one or more wind turbine power plants or one or more run-of-the-river hydroelectric power plants—without the inclusion of a dispatchable RE power plant such as the CSP plant 130 described above;
a mixed type VRE power plant, which utilises a combination of different types of VRE generation technologies, without the inclusion of a dispatchable RE power plant; and
a mixed type VRE power plant and a dispatchable RE power plant (see FIG. 4); and
a dispatchable RE power plant—such as one or more CSP plants 130 as described above, or one or more pumped hydroelectric power plants—without the inclusion of a VRE power plant.

FIG. 4 is a schematic block diagram of a hybrid electrical power generation system 1100 according to one such other embodiment of the present invention. This embodiment is substantially identical to the hybrid electrical power generation system 100 described above. Accordingly the following description of this embodiment will only address significant differences between the two systems.

One significant difference between the two systems is the utilisation of a mixed type VRE power plant 1150 including at least one PV power plant 1120 (with PV panels 1122 and inverter(s) 1124) and one or more wind turbine power plants 1115, in addition to a controller 1110, a CSP plant 1130, a combustion power plant 1160 and a BESS 1170. Accordingly, the controller 1110 is configured to selectively dispatch each of the at least one PV power plant 1120 and one or more wind turbine power plants 1115 within the VRE power plant 1120, the CSP plant 1130, the combustion power plant 1160, and/or the BESS 1170 in order to supply a given electrical demand to an electrical load 1010. As was the case with the previous embodiment, each of the power plants and the BESS 1170 have associated auxiliary electrical loads that also must be met when supplying the electrical load 1010 with the electrical demand.

Another significant difference apparent from a comparison between FIGS. 1 and 4 is that the VRE power plant 1120 is no longer restricted to daytime operation, as the inclusion of the one or more wind turbines 1115 allows the VRE power plant 1120 to be dispatched during the night time operation in the presence of suitable wind conditions. The dispatch and charging operations of the BESS 1170 are also extended into the night time operation to account for this night time dispatchability of the VRE power plant 1120.

It will be appreciated that, even if the VRE power plant 1120 were to be restricted to daytime operation, e.g. in the case of the PV plant 120 of hybrid electrical power generation system 100 described above, extending the dispatch and charging operations of the BESS 1170 may combine advantageously with the operation of the CSP plant 1130. For example, the BESS 1170 also can be used to provide an additional layer of redundancy for the CSP generator 1135.

Broadly, during the daytime operation, if there is enough sunlight, the PV panels 1122 and inverter(s) 1124 of the VRE power plant 1120 will generate electrical power, which the controller 1110 will dispatch to the electrical load 1010 and/or to the BESS 1170 if charging of the BESS 1170 is required. In addition, during both the daytime and night time operations, if there is enough wind, the one or more wind turbines 1115 of the VRE power plant 1120 will generate electrical power, which the controller 1110 will dispatch to the electrical load 1010 and/or to the BESS 1170 if charging of the BESS 1170 is required. The controller 1110 is configured to dispatch the BESS 1170 if the electrical power generated by the VRE power plant 1120 is not capable of supplying the electrical demand to the electrical load 1010. If the VRE power plant 1120 and the BESS 1170 are incapable of supplying the given electrical demand to the electrical load 1010, the controller 1110 is configured to dispatch the combustion power plant 1160 to supply the given electrical demand to the electrical load.

### Method of Simulating the Hybrid Electrical Power Generation System 100

In the following, an overview of an example environment illustrating different systems involved in certain embodiments will be described, followed by a description of a computer system which can be configured in various ways to perform the embodiments/various features thereof as described herein. Following this, an example simulation software tool will be described.

### Example Environment for Simulating the Hybrid Electrical Power Generation System 100

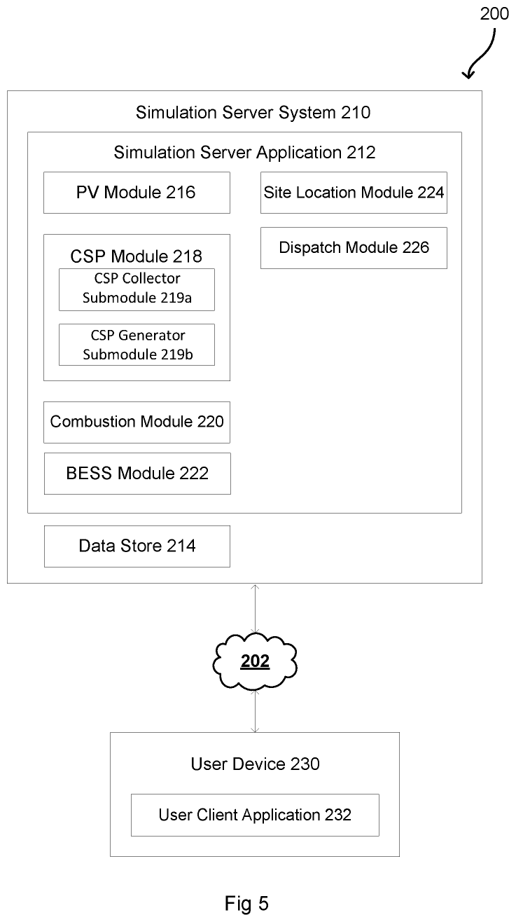

FIG. 5 illustrates an example environment 200 in which embodiments and features of a method for simulating the hybrid electrical power generation system 100 are implemented. Example environment 200 includes a communications network 202, which interconnect a simulation server system 210 and a user device 230.

The simulation server system 210 includes a simulation server application 212 (server application 212 for short) and a simulation server system data store 214 (data store 214 for short). The data store 214 is used for storing data related to functions performed by the simulation server system 210, for example, weather data, PV generator operating data, CSP generator operating data, combustion generator operating data, BESS operating data, and/or output data generated by the server application 212.

The server application 212 configures the simulation server system 210 to provide server side functionality for client applications (e.g. client application 232). Generally speaking, this involves receiving and responding to requests from client applications (e.g. client applications 232 discussed below). The server application 212 may be a web server (for interacting with web browser clients) or an application server (for interacting with dedicated application clients). While PC server system 210 has been illustrated with a single server application 212, it may provide multiple server applications (e.g. one or more web servers and/or one or more application servers).

In this example, the server application 212 includes a PV module 216 configured to receive and calculate PV generator operating data, a CSP module 218 configured to receive and calculate CSP operating data, a combustion module 220 configured to receive and calculate combustion generator data, and a BESS module 222 configured to receive and calculate BESS operating data. Each of the PV module 216, CSP module 218, combustion module 220, and BESS module 222 are configured to store the collected data on the data store 214. The CSP module 218 may include a CSP collector submodule 219a and a CSP generator submodule 219b.

Each of the PV module 216, the CSP collector submodule 219a, the CSP generator submodule 219b, the combustion module 220, and the BESS module 222 may calculate one or more parameters of the PV power plant 120, the CSP collector 131, the CSP generator 135, the TESS 133, the combustion power plant 160, and the BESS 170, respectively, based on the operating data they receive.

The server application 212 also has a dispatch module 226 configured to determine the operating status and dispatch each of the PV power plant 120, the CSP plant 130, the combustion power plant 160, and the BESS 170.

In certain embodiments, the simulation server system 210 is a scalable system. Depending on demand from clients (and/or other performance requirements), compute nodes can be provisioned/de-provisioned on demand. As an example, if there is high client demand additional server applications 212 may be provisioned to cater for that demand. In this case, each functional component of the simulation server system 210 may involve one or several applications running on the same or separate computer systems, each application including one or more application programs, libraries, APIs or other software that implements the functionality described herein.

The user device 230 includes a client application 232, which, when executed by the user device 230 (e.g. by a processing unit such as 302 described below), configures the user device 230 to provide simulation functionality to allow users to simulate the hybrid electrical power generation system 100. This involves communicating with the simulation server system 210 (and, in particular, the server application 212).

In the present example, while a single user device 230 has been depicted, environment 200 may include multiple user devices 230, each configured to interact with the simulation server system 210. User device 230 may be any form of computing device. Typically, user device 230 will be personal computing devices—e.g. a desktop computer, laptop computer, tablet computer, smart phone, or other computing device.

Communications between the various systems in environment 200 are via the communications network 202. Communications network 202 may be a local area network, public network (e.g. the Internet), or a combination of both.

While environment 200 has been provided as an example, alternative system environments/architectures are possible. In alternative embodiments that utilise different combinations of RE power generation technologies with the combustion power plant, a server application of the environment may include any RE module configured to receive and calculate RE generator operating data of the respective RE power plant, said RE module being further configured to store the collected data on the data store. For example, an environment in which embodiments and features of a method for simulating the hybrid electrical power generation system 1100 are implemented would differ from environment 200 at least by the server application 212 further including a wind module configured to receive and calculate wind generator operating data of the one or more wind turbines. In such an embodiment, the wind module and the PV module could be combined within a single VRE module.

### Example Computer Processing Systems

The features and techniques of the method for simulating the hybrid power generation systems 100 and 1100 described herein are implemented using one or more computer processing systems. For example, in networked environment 200 described above and user device 230 may be computer processing systems (for example, a personal computer, tablet/phone device, or other computer processing system). Similarly, the various functions performed by the simulation server system 210 are performed by one or more computer processing systems (e.g. server computers or other computer processing systems).

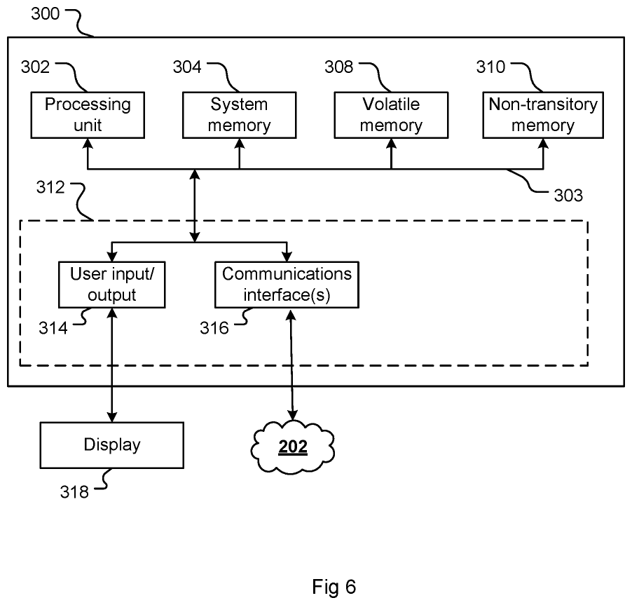

FIG. 6 provides a block diagram of a computer processing system 300 configurable to perform various functions described herein. System 300 is a general purpose computer processing system. It will be appreciated that FIG. 6 does not illustrate all functional or physical components of a computer processing system. For example, no power supply or power supply interface has been depicted, however system 300 will either carry a power supply or be configured for connection to a power supply (or both). It will also be appreciated that the particular type of computer processing system will determine the appropriate hardware and architecture, and alternative computer processing systems suitable for implementing features of the present disclosure may have additional, alternative, or fewer components than those depicted.

Computer processing system 300 includes at least one processing unit 302. The processing unit 302 may be a single computer processing device (e.g. a central processing unit, graphics processing unit, or other computational device), or may include a plurality of computer processing devices. In some instances, where a computer processing system 300 is described as performing an operation or function all processing required to perform that operation or function will be performed by processing unit 302. In other instances, processing required to perform that operation or function may also be performed by remote processing devices accessible to and useable by (either in a shared or dedicated manner) system 300.

Through a communications bus 303, the processing unit 302 is in data communication with a one or more machine readable storage (memory) devices which store instructions and/or data for controlling operation of the processing system 300. In this example system 300 includes a system memory 304, volatile memory 308 (e.g. random access memory such as one or more DRAM modules), and non-volatile memory 310 (e.g. one or more hard disk or solid state drives).

System 300 also includes one or more interfaces, indicated generally by 312, via which system 300 interfaces with various devices and/or networks. Generally speaking, other devices may be integral with system 300, or may be separate. Where a device is separate from system 300, connection between the device and system 300 may be via wired or wireless hardware and communication protocols, and may be a direct or an indirect (e.g. networked) connection.

Wired connection with other devices/networks may be by any appropriate standard or proprietary hardware and connectivity protocols. For example, system 300 may be configured for wired connection with other devices/communications networks by one or more of: Universal Serial Bus (USB); eSATA; Thunderbolt; Ethernet; HDMI. Other wired connections are possible.

Wireless connection with other devices/networks may similarly be by any appropriate standard or proprietary hardware and communications protocols. For example, system 300 may be configured for wireless connection with other devices/communications networks using one or more of: infrared; BlueTooth; WiFi; near field communications (NFC); Global System for Mobile Communications (GSM), Enhanced Data GSM Environment (EDGE), long term evolution (LTE), wideband code division multiple access (W-CDMA), code division multiple access (CDMA). Other wireless connections are possible.

Generally speaking, and depending on the particular system in question, devices to which system 300 connects—whether by wired or wireless means—include one or more input devices to allow data to be input into/received by system 300 for processing by the processing unit 302, and one or more output device to allow data to be output by system 300. Example devices are described below, however, it will be appreciated that not all computer processing systems will include all mentioned devices, and that additional and alternative devices to those mentioned may well be used.

For example, system 300 may include or connect to one or more input devices by which information/data is input into (received by) system 300. Such input devices may include keyboards, mice, trackpads, microphones, accelerometers, proximity sensors, GPS devices and the like. System 300 may also include or connect to one or more output devices controlled by system 200 to output information. Such output devices may include devices such as a CRT displays, LCD displays, LED displays, plasma displays, touch screen displays, speakers, vibration modules, LEDs/other lights, and such like. System 300 may also include or connect to devices which may act as both input and output devices, for example memory devices (hard drives, solid state drives, disk drives, compact flash cards, SD cards and the like) which system 300 can read data from and/or write data to, and touch screen displays which can both display (output) data and receive touch signals (input).

Where the system 300 is user device 230, the system 300 includes or connects to a display 318 to output information. The display 318 may be a CRT display, LCD display, LED display, plasma display, or a touch screen display that can both display (output) data and receive touch signals (input).

System 300 also includes one or more communications interfaces 316 for communication with a network, such as network 202 of environment 200. Via the communications interface(s) 316 system 300 can communicate data to and receive data from networked devices, which may themselves be other computer processing systems.

System 300 may be any suitable computer processing system, for example, a server computer system, a desktop computer, a laptop computer, a netbook computer, a tablet computing device, a mobile/smart phone, a personal digital assistant, or an alternative computer processing system.

System 300 stores or has access to computer applications (also referred to as software or programs)—i.e. computer readable instructions and data which, when executed by the processing unit 302, configure system 300 to receive, process, and output data. Instructions and data can be stored on non-transitory machine readable medium accessible to system 300. For example, instructions and data may be stored on non-transitory memory 310. Instructions and data may be transmitted to/received by system 300 via a data signal in a transmission channel enabled (for example) by a wired or wireless network connection over interface such as 312.

Applications accessible to system 200 will typically include an operating system application such as Windows™, macOS™, iOS™, Android™, Unix™, Linux™, or other operating system.

System 300 also stores or has access to applications which, when executed by the processing unit 302, configure system 300 to perform various computer-implemented processing operations described herein. For example, and referring to the networked environment of FIG. 5 above a user device such as 230 includes a client application 232 which configures the user device 230 to perform various operations described herein. Similarly, simulation server system 210 includes a server application 212 which configures the server system 210 to perform various operations described herein.

### Example Simulation Method

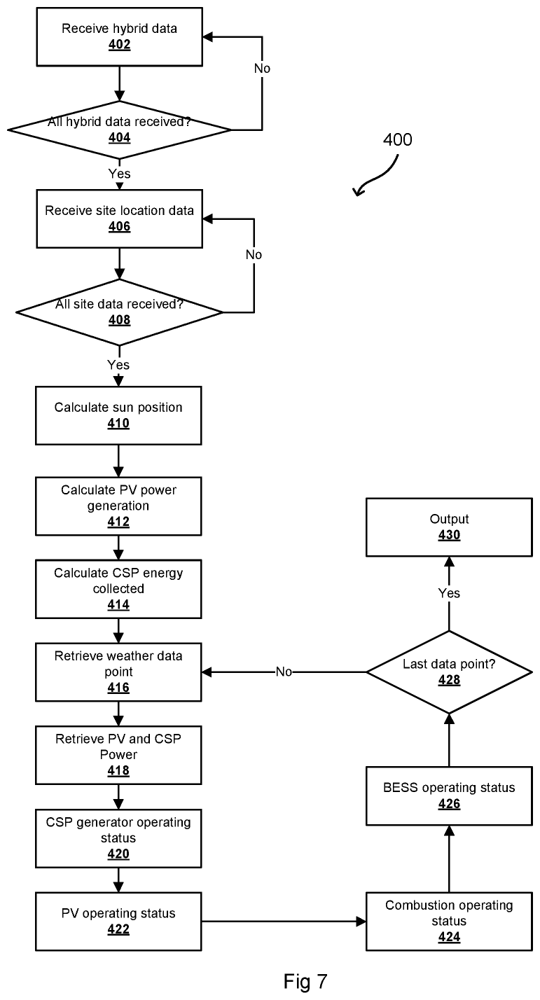

FIG. 7 is a flowchart of a method 400 of simulating the hybrid electrical power generation system 100. The method 400 utilises site location data for a particular location at which the hybrid electrical power generation system 100 is to be installed in order to simulate the hybrid electrical power generation system 100. The site location data includes a weather dataset and geographical data. The weather dataset may be a historical weather dataset for the location that the hybrid electrical power generation system 100 will be installed. Alternatively, the weather dataset may be a representative weather dataset for the location that the hybrid electrical power generation system 100 will be installed.

The weather dataset includes a plurality of weather data points. Each weather data point may define the solar irradiance (e.g. direct normal irradiance, direct horizontal irradiance, and global horizontal irradiance), wind speed, wind direction, temperature, air pressure, and a timestamp indicating the time and date the weather data point was recorded. The weather data points may be recorded at regular time intervals (e.g. every one minute, every five minutes, or every hour). It will be appreciated that shorter time intervals between each weather data point will provide a more accurate simulation of the behaviour of the hybrid electrical power generation system 100.

The geographical data includes the coordinates (i.e. latitude and longitude), the altitude, and the time zone of the location at which the hybrid electrical power generation system is to be installed.

At 402, the server application 212 receives hybrid electrical power generation system data relating to the hybrid electrical power generation system 100 from a user (e.g. using the client application 232 on user device 230). In particular, PV module 216 receives PV operating data relating to the PV power plant 120, the CSP module 218 receives CSP operating data relating to the CSP plant 130, the combustion module 220 receives combustion power plant operating data relating to the combustion power plant 160, and the BESS module 222 receives BESS operating data relating to the BESS 170. For example, the client application 232 may generate and display a hybrid electrical power generation system data user interface on the display 318 of the user's user device 230 via which the user may input the PV operating data, CSP operating data, combustion operating data, and BESS operating data, causing this data to be communicated to (or otherwise received/retrieved) by the PV module 216, CSP module 218, combustion module 220, and BESS module 222, respectively. The server application 212 stores the hybrid electrical power generation system data in the data store 214.

The simulation tool may be configured to require that particular operating data fields (i.e. required operating data fields) must be populated before the simulation of the hybrid electrical power generation system 100 can commence. The requirement may be enforced server side or client side.

For example, where required operating data fields are enforced server side, at 404, the server application 212 determines if the hybrid electrical power generation system data received at 402 includes hybrid electrical power generation system data relating to the required operating data fields. If so, the server application 212 proceeds to step 406. If not, the server application 212 may alert a user to any missing operating data fields (e.g. by causing a prompt to be displayed on a user interface displayed by client application 232, by an electronic communication to the users, or by alternative means) before processing returns to 402 to await for and receive further operating data.

Alternatively, if required operating data fields are enforced client side, the client application 232 may be configured to prevent simulation of the hybrid electrical power generation system 100 until all required operating data fields have been populated. For example, client application 232 may be configured to prevent to prevent the user commencing the simulation until all required operating data fields have been populated. For example, client application 232 may prevent activation of a control displayed by a user interface that begins the simulation until all required operating data fields have been provided.

In certain embodiments, the required operating data fields are system defined. In alternative embodiments, server application 212 may be configured to allow users to define additional (and/or alternative) required operating data fields. For example, server application 212 may define a set of required operating data fields and an organization using the simulation tool may add further required operating data fields.

The project data may also include operating data relating to one or more operating data fields that do not need to be populated in order to simulate the hybrid electrical power generation system 100 (i.e. optional operating data fields).

At 406, the site location module 224 receives site location data relating to the location at which the hybrid electrical power generation system 100 is to be installed from the user (e.g. using the client application 232 on user device 230). The site location data includes a historical weather dataset and geographical data.

As an example, the client application 232 may generate and display a site location data user interface on the display 318 of the user's user device 230 via which the user may input the historical or historical average weather dataset and the geographical data, which is subsequently communicated to (or otherwise received/retrieved) by the site location module 224.

In an alternative embodiment, the user may input a file location of the historical weather dataset in the site location data user interface, which can be accessed/retrieved by the site location module 224.

The simulation tool may be configured to require that particular weather data fields and geographical data fields (i.e. required site location data fields) must be populated before the simulation of the hybrid electrical power generation system 100 can commence. The requirement may be enforced server side or client side.

For example, where required site location data fields are enforced server side, at 408, the site location module 224 determines if the site location data received at 406 includes site location data relating to the required site location data fields and if the historical weather dataset is in a suitable format. If so, the site location module 224 proceeds to step 410. If not, the site location module 224 may alert a user to any missing data (e.g. by causing a prompt to be displayed on a user interface displayed by client application 232, by an electronic communication to the project creator, or by alternative means) before processing returns to 406 to await for and receive further site location data.

Where the site location module 224 access/retrieves the historical weather dataset from a file location, at 408, the site location module 224 additionally determines if the file location is accessible and valid. If not, the site location module 224 may alert a user that the historical weather dataset cannot be accessed/retrieved from the given file location (e.g. by causing a prompt to be displayed on a user interface displayed by client application 232, by an electronic communication to the project creator, or by alternative means) before processing returns to 406 to await for the user to rectify this issue. If the file location of the historical weather dataset is accessible and valid, the site location module 224 performs the checks discussed above in paragraph [0144].

At 410, the site location module 224 calculates the sun position (i.e. altitude and azimuth) for each weather data point of the historical weather dataset taking into account the coordinates, altitude, and time zone at the location the hybrid electrical generation power system 100 is to be installed. The sun position may be calculated using any suitable methods known in the art. The site location module 224 stores the calculated sun position as sun position data for each weather data point in the data store 214. For example, the site location module 224 may store the sun position for each weather data point in a sun position record defined by a sun position table stored in the data store 214. An example sun position table may define the following information:

| | | | |
|---|---|---|---|
| Weather data point | Timestamp | Sun altitude | Sun Azimuth |

At 412, the PV module 216 calculates the potential electrical power generated by the PV power plant 120 for each weather data point. The PV module 216 accesses/retrieves the PV operating data for the PV power plant 120 and the sun position data for each weather data point from the data store 214. For each weather data point, the PV module 216 determines the potential electrical power generated by the PV power plant 120 taking into account the PV operating data, the sun position data, and the weather data of the weather data point. For example, the PV module 216 takes into account if the PV panels of the PV power plant 120 track the sun position or, if the PV panels are stationary, the angle at which the PV panels are installed. The potential electrical power generated by the PV power plant 120 may be calculated using any suitable methods known in the art for tracking PV power plants and stationary PV power plants. The PV module 216 stores the potential electrical power generated by the PV power plant 120 for each weather data point in the data store 214. For example, the PV module 216 may store the potential electrical power generated by the PV power plant 120 for each weather data point in a PV and CSP simulation record defined by a PV and CSP simulation table stored in the data store 214. An example PV and CSP simulation table may define the following information:

| | | | | |
|---|---|---|---|---|
| | | Power | Thermal energy | Potential |
| Weather | | generated by | collected | additional |
| data | | PV power | by CSP | thermal |
| point | Timestamp | plant 120 | receiver 136 | energy storage |

After the PV module 216 has determined the potential electrical power generated by the PV power plant 120 for each weather data point, processing proceeds to step 414.

At 414, the CSP module 218 calculates the potential thermal energy collected by the CSP receiver 136 that could be added to the hot energy storage tank 138 for each weather data point. The CSP module 218 accesses/retrieves the CSP operating data for the CSP plant 130 and the sun position data for each weather data point from the data store 214. For each weather data point, the CSP module 218 determines the potential thermal energy collected by the receiver 136 taking into account the CSP operating data, the sun position data, and the weather data of the weather data point. For example, the CSP module 218 takes into account if the CSP collector 131 is a trough type CSP collector, dish type CSP collector, tower type CSP collector, or Fresnel type CSP collector. The potential thermal energy collected by the CSP receiver 136 may be calculated using any suitable methods known in the art for CSP collectors (e.g. trough, dish, tower, and Fresnel type CSP collectors). The CSP module 218 stores the potential thermal energy collected by the CSP receiver 136 for each weather data point in the data store 214. For example, the CSP module 218 may store the potential thermal energy collected by the CSP receiver 136 for each weather data point in the corresponding PV and CSP simulation record discussed above for the weather data point.

The CSP module 218 applies the calculated thermal energy collected by the CSP receiver 136 at each weather data point (minus any efficiency losses of the CSP receiver 136) to the CSP heat transfer medium disposed in the HTF network 158 at the outlet 142 of the CSP receiver 136. The CSP module 218 then determines how much thermal energy is transferred by CSP heat transfer medium from the outlet 142 of the CSP receiver 136 to the hot energy storage tank 138 via hot heat transfer piping network 140 and the storage tank heat exchanger 132.

For an actual CSP plant 130, there may be several arrays of CSP collectors 131 and, therefore, several CSP receivers 136. The CSP receivers 136 would be distributed across the hybrid electrical power generation system 100, adding thermal energy at different points within the hybrid electrical power generation system 100. For the ease of modelling, however, the thermal energy entering the hot heat transfer network 140 from all the CSP receivers 136 is assumed to originate at a single point which then travels the entire length of the hot heat transfer piping network 140, to the storage tank heat exchanger 132, and back to the CSP receivers 136 via the entire length of the cold heat transfer network 141. To simulate multiple CSP receivers 136 adding thermal energy at different points within the hybrid electrical power generation system 100, an adjustment factor may be applied to the CSP collector 131, which corrects the cumulative thermal energy collected by each CSP receiver 136 to the outlet 142. This adjustment factor may be provided with the CSP collector data received and/or calculated at 402.

For each weather data point, the CSP module 218 determines the potential additional thermal energy for hot energy storage tank 138. The potential additional thermal energy for the hot energy storage tank 138 is the potential thermal energy that could be added to the hot energy storage tank 138 for each weather data point. For each weather data point, the potential additional thermal energy for hot energy storage tank 138 is the thermal energy collected by the CSP receiver 136 for the weather data point less any losses due to the efficiency of the CSP receiver 136 transferring thermal energy to the CSP heat transfer medium disposed in the HTF network 158, radiative losses from the hot heat transfer piping network 140, and losses due to the efficiency of the storage tank heat exchanger 132 transferring thermal energy from the CSP heat transfer medium to the heat storage medium. The CSP module 218 stores the potential additional thermal energy for hot energy storage tank 138 for each weather data point in the data store 214. For example, the CSP module 218 may store the potential additional thermal energy for hot energy storage tank 138 for each weather data point in the corresponding PV and CSP simulation record discussed above for the weather data point.

The efficiency losses of the CSP receiver 136 and the efficiency losses of the storage tank heat exchanger 132 may be calculated based on the efficiency of the CSP receiver 136 and the storage tank heat exchanger 132. The efficiency of the CSP receiver 136 and the efficiency of the storage tank heat exchanger 132 may be provided with the CSP operating data received at 402.

The radiative losses through the hot heat transfer piping network 140 may be calculated using any suitable methods known in the art. When calculating the radiative losses the following information may be taken into account: the material the hot heat transfer piping network 140 is constructed from; the overall length of the hot heat transfer piping network 140; the radius of the hot heat transfer piping network 140; and the type and thickness of any insulation surrounding the hot heat transfer piping network 140. This information may be provided with the CSP operating data received at 402.

The temperature of the heat transfer fluid may also be taken into account when calculating the radiative losses through the hot heat transfer piping network 140. This may be calculated based on the temperature of the heat transfer fluid for the previous weather data point, determining the density of the heat transfer fluid, the specific heat and volume of the heat transfer fluid. The specific heat and volume of the heat transfer fluid determines the temperature increase as a result of the thermal energy collected by the CSP receiver 136, which gives the heat transfer fluid temperature for the weather data point.

After the CSP module 218 has determined the potential thermal energy added to the hot energy storage tank 138 for each weather data point, processing proceeds to step 416.

At 416, the dispatch module 226 accesses the weather dataset and retrieves and begins processing a weather data point. The dispatch module 226 is configured to process the weather data points in chronological order. The dispatch module 226 determines the chronological based on the timestamps of each weather data point. Accordingly, in the first processing loop), the dispatch module 226 will retrieve and begin processing the first weather data point of the weather dataset. In subsequent processing loops, the dispatch module 226 will retrieve and begin processing the weather data points in chronological order. Alternatively, the dispatch module 226 may begin processing the weather data points chronologically from a predetermined start date provided with the hybrid electrical power generation system data at 402. After, the dispatch module 226 has retrieved a weather data point, the dispatch module 226 proceeds to step 418.

Reference to “the weather data point” below refers to the weather data point retrieved at step 416.

At step 418, the dispatch module 226 retrieves the electrical power generated by the PV power plant 120 determined at 412 and the potential additional thermal energy storage determined at 414 for the weather data point from the data store 214. For example, the dispatch module 226 could retrieve this data from the PV and CSP simulation record relating to the weather data point in the PV and CSP simulation table stored on the data store 214. Once the dispatch module 226 retrieves this information, the dispatch module 226 proceeds to step 420.

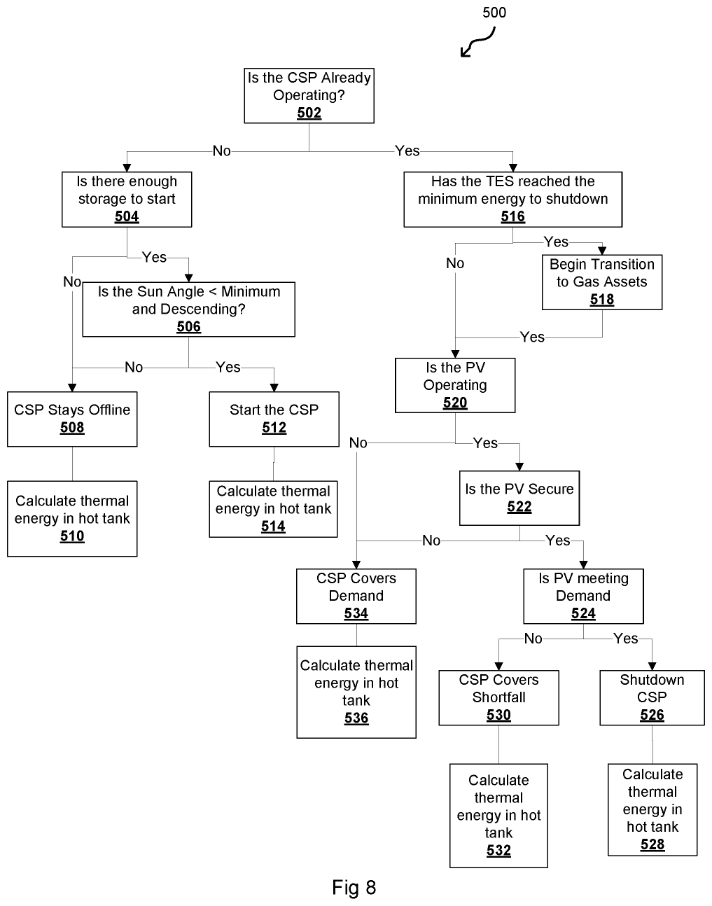

At 420, the dispatch module 226 determines the operational status of the CSP generator 135 for the weather data point. To determine the operational status of the CSP generator 135 for the weather data point, the dispatch module 226 performs sub-process 500 (see FIG. 8).

At 502, the dispatch module 226 determines if the CSP generator 135 was operating in the previous processed weather data point based on the operating status of the CSP generator 135 from the previous processed weather data point. If so, the dispatch module 226 proceeds to step 516. If not, the dispatch module 226 proceeds to step 504.

At 504, the dispatch module 226 determines if there is enough thermal energy stored in the hot energy storage tank 138 to start the CSP generator 135 based on the minimum thermal energy required to start the CSP plant 130. If so, the dispatch module 226 proceeds to step 506. If not, the dispatch module 226 proceeds to step 508.

At 506, the dispatch module 226 retrieves the sun position data determined at 410 for the weather data point from the data store 214 and determines if the sun is at the CSP minimum sun angle and, if required by the user, if the sun is descending. If not, the dispatch module 226 proceeds to step 508. If so, the dispatch module 226 proceeds to step 512. It will be appreciated that, in alternative embodiments, such a determination may not be required, or made using different parameters, such as time of day, hours until civil twilight, PV plant output, electricity price, etc.

At 508, the dispatch module 226 determines that the CSP generator 135 remains offline (i.e. it is not operating) for the weather data point and proceeds to step 510.

At 510, the dispatch module 226 calculates the thermal energy stored in the hot energy storage tank 138 for the weather data point. To determine the thermal energy in the hot energy storage tank 138 for the weather data point, the dispatch module 226 adds the potential additional thermal energy for hot energy storage tank 138 determined at 414 for the weather data point with the thermal energy in the hot energy storage tank 138 determined for the previous processed weather data point less any radiative thermal losses from the hot energy storage tank 138.

The dispatch module 226 determines if this calculation is greater than the maximum storage capacity of the hot energy storage tank 138. If not, the dispatch module 226 sets the result of this calculation as the thermal energy in the hot energy storage tank 138 for the weather data point and records this in the data store 214.

If the result of this calculation is greater than the maximum storage capacity of the hot energy storage tank 138, the dispatch module 226 only adds a portion of the potential additional thermal energy storage determined at 414 for the weather data point to bring the thermal energy in the hot energy storage tank 138 to the maximum storage capacity of the hot energy storage tank 138. In this case, for the weather data point, the dispatch module 226 sets the thermal energy in the hot energy storage tank 138 to the maximum storage capacity of the hot energy storage tank 138, calculates the amount of the potential additional thermal energy storage not added to the hot energy storage tank 138 (i.e. lost thermal energy), and records this in the data store 214.

As an example, the dispatch module 226 may record the operational status of the CSP generator 135 determined at 508, the thermal energy in the hot energy storage tank 138, and the lost thermal energy for the weather data point in a CSP operation record defined by a CSP operation table stored in the data store 214. An example CSP operation table may define the following:

| Weather | Timestamp | Status of | % of | Power supplied to | Thermal energy | Lost |
|---|---|---|---|---|---|---|
| data point | | CSP | electrical | electrical load 10 by | in hot energy | thermal |
| | | generator | demand | CSP generator 135 | storage tank 138 | energy |
| | | 135 | supplied | | | |

At this point, the dispatch module 226 has completed the sub-process 500 and processing proceeds to step 422 of the method 400 (see FIG. 7).

The radiative losses from the hot energy storage tank 138 may be calculated using any suitable methods known in the art. When calculating the radiative losses the following information may be taken into account: the material the hot energy storage tank 138 is constructed from; the height and diameter of the hot energy storage tank 138; and the type and thickness of any insulation surrounding the hot energy storage tank 138. This information may be provided with the CSP operating data received at 402. Alternatively, the radiative losses from the hot energy storage tank 138 may be a constant value applied to the hot tank for each weather data point. This constant value may be provided with the CSP operating data received at 402.

When the simulation of the hybrid electrical power generation system 100 begins, the CSP module 218 may set the thermal energy in the hot energy storage tank 138 to zero. Alternatively, the user may be able to set the thermal energy in the hot energy storage tank 138 to a predetermined value when the simulation begins. This may be done when providing the hybrid electrical power generation system data at 402.

At 512, the dispatch module 226 updates the status of the CSP generator 135 for the weather data point to indicate that the CSP generator 135 has been instructed to start-up. In some embodiments, as part of step 512, the dispatch module 226 may also determine if the BESS 170 is at or above the secure level 176 for the weather data point. If so, the dispatch module 226 may allow the start-up of the CSP generator 135 to continue as normal (e.g. the dispatch module 226 may make no further intervention until the CSP generator 135 has started up and/or is dispatched). If not, the dispatch module 226 may dispatch at least one of the power plants of the hybrid electrical power generation system to charge the BESS 170 during the CSP generator 135 start-up process. For example, the dispatch module 226 may dispatch the CSP generator 135 to charge the BESS 170 as part of the CSP generator 135 start-up process. Alternatively, or in addition, the dispatch module 226 may dispatch the PV power plant 120 and/or the combustion power plant 160, depending on their respective operating status. In some embodiments, the dispatch module 226 may be configured such that it is prevented from dispatching the CSP generator 135 until it is determined that the BESS 170 is at or above the secure level 176.

At 514, the dispatch module 226 determines the thermal energy stored in the hot energy storage tank 138 for the weather data point. To determine the thermal energy in the hot energy storage tank 138 for the weather data point, the dispatch module 226 adds the potential additional thermal energy storage determined at 414 for the weather data point with the thermal energy in the hot energy storage tank 138 determined for the previous processed weather data point less any radiative thermal losses from the hot energy storage tank 138 (discussed above in [0170]) and the thermal energy required to start the CSP generator 135. The CSP module 218 records the operating status of the CSP generator 135 and the thermal energy in the hot energy storage tank 138 in the data store 214 (e.g. in the CSP operation record relating to the weather data point defined by the CSP operation table discussed above in [0168]) for the weather data point. At this point, the dispatch module 226 has completed the sub-process 500 and processing proceeds to step 422 of the method 400 (see FIG. 7).

The thermal energy required to start the CSP generator 135 may be defined by the original equipment manufacturer of the CSP generator 135 and this operating data may form part of the CSP operating data received at 402.

At 516, the dispatch module 226 determines if the thermal energy shutdown level of the CSP generator 135 has been met for the weather data point. If so, the dispatch module 226 proceeds to step 518. If not, the dispatch module 226 proceeds to step 520.

At 518, the dispatch module 226 issues a command to the combustion module 220 to start-up the combustion power plant 160 for the weather data point and proceeds to step 520.

At 520, the dispatch module 226 determines if the PV power plant 120 is operating based on whether or not the PV power plant 120 is generating electrical power for the weather data point. If so, the dispatch module 226 proceeds to step 522. If not, the dispatch module 226 proceeds to step 534.

At 522, the dispatch module 226 determines if the BESS 170 is at the secure level 176 for the weather data point. If so, the dispatch module 226 proceeds to step 524. If not, the dispatch module 226 proceeds to step 534.

At the beginning of the simulation, the state of charge of the BESS 170 may be set to the maximum depth of discharge of the BESS 170 by the simulation tool. Alternatively, the user may set the state of charge of the BESS 170 to be at a desired state of charge at the beginning of the simulation (e.g. at 40% of the maximum capacity of the BESS). This may be done when providing the hybrid electrical power generation system data at 402.

At 524, the dispatch module 226 determines if the electrical power generated by the PV power plant 120 determined at 412 for the weather data point is able to meet the electrical demand. If so, the dispatch module 226 proceeds to step 526. If not, the dispatch module 226 proceeds to step 530.

At 526, the dispatch module 226 updates the operating status of the CSP generator 135 from operating to not operating (e.g. taking the CSP generator 135 offline).

At 528, the dispatch module 226 calculates the thermal energy in the hot energy storage tank 138 using the same method describe above at step 510. The dispatch module 226 records the operating status of the CSP generator 135 and the thermal energy in the hot energy storage tank 138 in the data store 214 for the weather data point. For example, this information may be defined in the CSP operation record relating to the weather data point defined by the CSP operation table stored on the data store 214 as discussed above in [0168]. At this point, the dispatch module 226 has completed the sub-process 500 and processing proceeds to step 422 of the method 400 (see FIG. 7).

At 530, for the weather data point, the dispatch module 226 determines the proportion of the electrical demand that can be supplied to the electrical load 10 by the PV power plant 120 based on the electrical power generated by the PV power plant 120 determined at 412 for the weather data point. The dispatch module 226 then determines the remaining electrical power (i.e. the electrical power shortfall) that is required to supply the electrical load 10 with the electrical demand and utilises (i.e. dispatches) the CSP generator 135 to supply the electrical power shortfall.

At 532, the dispatch module 226 determines how much thermal energy the CSP generator 135 requires to supply the electrical load 10 with the remaining electrical power determined at 530 for the weather data point. Subsequently, the dispatch module 226 determines the amount of thermal energy that is consumed from the hot energy storage tank 138 by the CSP generator 135 via the generator heat exchanger 134 in order to supply the remaining electrical power to the electrical load 10 based on the efficiency of the CSP generator 135 and the efficiency of the generator heat exchanger 134. The efficiency of the CSP generator 135 and the efficiency of the generator heat exchanger 134 may be received as part of the CSP operating data at 402.

The dispatch module 226 then calculates the thermal energy in the hot energy storage tank 138 for the weather data point. To determine the thermal energy in the hot energy storage tank 138 for the weather data point, the dispatch module 226 adds the potential additional thermal energy storage determined at 414 for the weather data point to the thermal energy in the hot energy storage tank 138 determined for the previous processed weather data point less any radiative thermal losses from the hot energy storage tank 138 (discussed above in [0170]) and the thermal energy consumed from the hot energy storage tank 138 determined at 530. Similar to what was described above in [0167], if the result of this calculation is greater than the maximum storage of the hot energy storage tank 138, the dispatch module 226 only adds a portion of the potential additional thermal energy determined at 414 for the weather data point to bring the thermal energy in the hot energy storage tank 138 to the maximum storage of the hot energy storage tank 138 and records the remainder of the potential additional thermal energy as lost thermal energy. The dispatch module 226 records the operating status of the CSP generator 135, the electrical power supplied by the CSP generator 135, the thermal energy in the hot energy storage tank 138, and any thermal energy losses in the data store 214 for the weather data point in the data store 214. For example, this information may be defined in the CSP operation record relating to the weather data point defined by the CSP operation table stored on the data store 214 as discussed above in [0168]. At this point, the dispatch module 226 has completed the sub-process 500 and processing proceeds to step 422 of the method 400 (see FIG. 7).

At 534, the dispatch module 226 utilises (i.e. dispatches) the CSP generator 135 to supply the electrical load 10 with the electrical demand for the weather data point.

At 536, the dispatch module 226 determines how much thermal energy the CSP generator 135 requires to supply the electrical load 10 with the electrical demand. Subsequently, the dispatch module 226 determines the amount of thermal energy that is consumed from the hot energy storage tank 138 by the CSP generator 135 in order to supply the electrical load 10 with the electrical demand based on the efficiency of the CSP generator 135 and the efficiency of the generator heat exchanger 134.

The dispatch module 226 then calculates the thermal energy in the hot energy storage tank 138 using the same method describe above at step 532. The dispatch module 226 records the operating status of the CSP generator 135, the electrical power supplied by the CSP generator 135, and the thermal energy in the hot energy storage tank 138 in the data store 214 for the weather data point. For example, this information may be defined in the CSP operation record relating to the weather data point defined by the CSP operation table stored on the data store 214 as discussed above in [0168]. At this point, the dispatch module 226 has completed the sub-process 500 and processing proceeds to step 422 of the method 400 (see FIG. 7).

Once the dispatch module 226 determines the operating status of the CSP plant 130 for the weather data point, processing proceeds to step 422 of the method 400 (see FIG. 7).

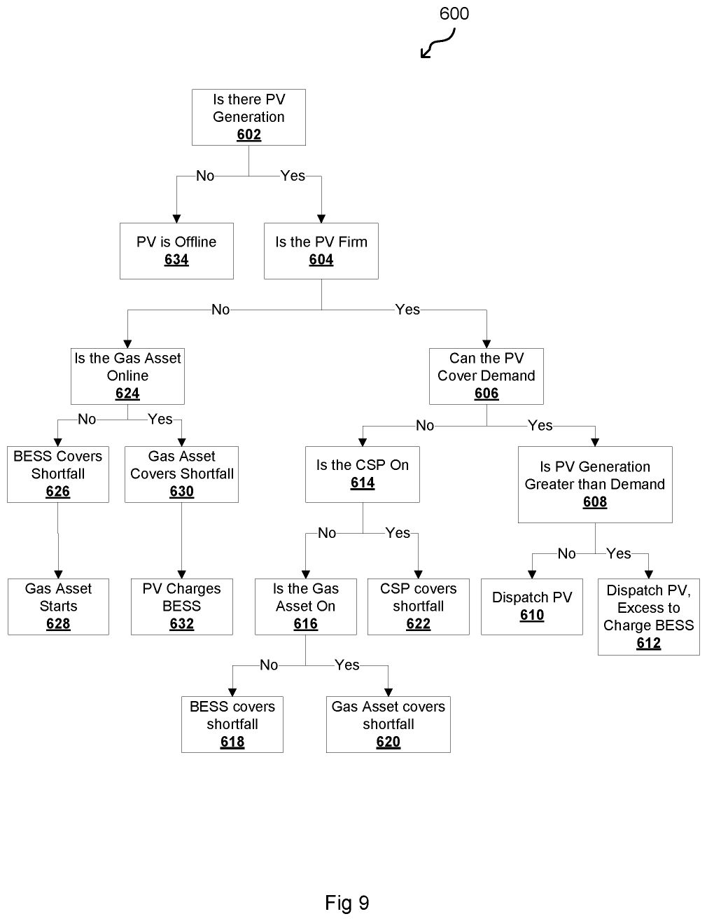

At 422, the dispatch module 226 determines the operational status of the PV power plant 120 for the weather data point. To determine the operational status of the PV power plant 120 for the weather data point, the PV module 216 performs sub-process 600 (see FIG. 9).

At 602, the dispatch module 226 determines if the PV power plant 120 can provide electrical power based on the potential electrical power generated by the PV power plant determined at 412 for the weather data point. If so, the dispatch module 226 proceeds to step 604. If not, the dispatch module 226 proceeds to step 634.

At 604, the dispatch module 226 determines if the BESS 170 is at or above the secure level 176 for the weather data point. If so, the dispatch module 226 proceeds to step 606. If not, the dispatch module 226 proceeds to step 624.

At 606, the dispatch module 226 determines if the electrical power generated by the PV power plant 120 determined at 412 for the weather data point is able to supply the electrical demand to the electrical load 10. If so, the dispatch module 226 proceeds to step 608. If not, the dispatch module 226 proceeds to step 614.

At 608, for the weather data point, the dispatch module 226 determines if the electrical power generated by the PV power plant 120 is equal to or greater than the electrical demand. If the electrical power generated by the PV power plant 120 is equal to the electrical load, the dispatch module 226 proceeds to step 610. If the electrical power generated by the PV power plant 120 is greater than the electrical demand, the dispatch module 226 proceeds to step 612.

At 610, the dispatch module 226 utilises (i.e. dispatches) the PV power plant 120 to supply the electrical demand to the electrical load 10. The PV module 216 records that the PV power plant 120 is operating for the weather data point and the electrical power delivered to the electrical load 10 by the PV power plant 120 in the data store 214. For example, the dispatch module 226 may record the operational status of the PV power plant 120 determined at 610 and the power delivered to the electrical load 10 for the weather data point in a PV operation record defined by a PV operation table stored in the data store 214. An example PV operation table may define the following:

| | | | | | | | | | |
|---|---|---|---|---|---|---|---|---|---|
| Weather | Time | Status | Power | Excess | Shortfall | Demand on | Demand | Demand | Demand on |
| data | stamp | of PV | supplied | electrical | | combustion | on | on CSP | combustion |
| point | | power | by PV | power | | power | BESS | plant | power plant |
| | | plant | power | | | plant 160 to | 170 to | 130 | 160 provide |
| | | 120 | plant 10 | | | cover | cover | cover | electrical load |
| | | | | | | shortfall | shortfall | shortfall | |

At this point, the dispatch module 226 has completed the sub-process 600 and processing proceeds to step 424 of the method 400 (see FIG. 7).

At 612, the dispatch module 226 utilises (i.e. dispatches) the PV power plant 120 to supply the electrical demand to the electrical load 10 and determines the amount of electrical power generated by the PV power plant 120 for the weather data point that is in excess of the electrical demand (i.e. the excess electrical power). The dispatch module 226 determines if the excess electrical power is to be added to the state of charge of the BESS 170 (i.e. to simulate charging of the BESS 170) at a later stage in the method 400 (discussed below with respect to sub-process 800).

The dispatch module 226 records the operating status of the PV power plant 120, the electrical power supplied to the electrical load 10 by the PV power plant 120, and the excess electrical power in the data store 214 for the weather data point. For example, this information may be defined in the PV operation record relating to the weather data point defined by the PV operation table stored on the data store 214 as discussed above in [0195]. At this point, the dispatch module 226 has completed the sub-process 600 and processing proceeds to step 424 of the method 400 (see FIG. 7).

At 614, for the weather data point, the dispatch module 226 determines if the CSP generator 135 is operating based on the status of the CSP generator 135 determined by the CSP module 218 at step 420. If not, the dispatch module 226 proceeds to step 616. If so, the dispatch module 226 proceeds to step 622.

At 616, the dispatch module 226 determines if the combustion power plant 160 is operating for the weather data point based on the status of the combustion power plant 160 from the previous processed weather data point. If not, the dispatch module 226 proceeds to step 618. If so, the dispatch module 226 proceeds to step 620.

At 618, for the weather data point, the dispatch module 226 determines the proportion of the electrical demand that can be supplied to the electrical load 10 by the PV power plant 120 based on the electrical power generated by the PV power plant 120 determined at 412 for the weather data point. The dispatch module 226 then determines the remaining electrical power (i.e. the electrical power shortfall) that is required to supply the electrical load 10 with the electrical demand. The dispatch module 226 subsequently utilises (i.e. dispatches) the PV power plant 120 to supply the electrical power generated by the PV power plant 120 determined at 412 to the electrical load and the dispatch module 226 demands the BESS 170 to contribute towards supplying the electrical power shortfall.

The dispatch module 226 records the operating status of the PV power plant 120, the electrical power supplied to the electrical load 10 by the PV power plant 120, the electrical power shortfall, and that the BESS 170 has been demanded to contribute towards supplying the electrical power shortfall for the weather data point in the data store 214. For example, this information may be defined in the PV operation record relating to the weather data point defined by the PV operation table stored on the data store 214 as discussed above in [0195]. At this point, the dispatch module 226 has completed the sub-process 600 and processing proceeds to step 424 of the method 400 (see FIG. 7).

At 620, for the weather data point, the dispatch module 226 determines the proportion of the electrical demand that can be supplied to the electrical load 10 by the PV power plant 120 based on the electrical power generated by the PV power plant 120 determined at 412 for the weather data point. The PV module 216 then determines the remaining electrical power (i.e. the electrical power shortfall) that is required to supply the electrical load 10 with the electrical demand. The dispatch module 226 subsequently utilises (i.e. dispatches) the PV power plant 120 to supply the electrical power generated by the PV power plant 120 determined at 412 to the electrical load 10 and the dispatch module 226 demands the combustion power plant 160 to contribute towards supplying the electrical power shortfall. The dispatch module 226 determines if the combustion power plant 160 can supply the electrical power shortfall at a later stage in the method 400 (discussed below with respect to sub-process 700).

The dispatch module 226 records the operating status of the PV power plant 120, the electrical power supplied to the electrical load 10 by the PV power plant 120, the electrical power shortfall, and that the combustion power plant 160 has been demanded to contribute towards supplying the electrical power shortfall in the data store 214. For example, this information may be defined in the PV operation record relating to the weather data point defined by the PV operation table stored on the data store 214 as discussed above in [0195]. At this point, the dispatch module 226 has completed the sub-process 600 and processing proceeds to step 424 of the method 400 (see FIG. 7).

At 622, for the weather data point, the dispatch module 226 utilises (i.e. dispatches) the PV power plant 120 to supply the electrical power generated by the PV power plant 120 determined at 412 to the electrical load 10 and the dispatch module 226 utilises (i.e. dispatches) the CSP plant 130 supply the electrical power shortfall determined at step 530.

The dispatch module 226 records the operating status of the PV power plant 120, the electrical power supplied to the electrical load 10 by the PV power plant 120, the electrical power shortfall, and that the CSP power plant 130 was utilised (i.e. dispatched) to supply the electrical power shortfall. For example, this information may be defined in the PV operation record relating to the weather data point defined by the PV operation table stored on the data store 214 as discussed above in [0195]. At this point, the dispatch module 226 has completed the sub-process 600 and processing proceeds to step 424 of the method 400 (see FIG. 7).

At 624, the dispatch module 226 determines if the combustion power plant 160 is operating using the same method described above at 616. If not, the dispatch module 226 proceeds to step 626. If so, the dispatch module 226 proceeds to step 630.

At 626, using the same method discussed above at 618, the dispatch module 226 utilises (i.e. dispatches) the PV power plant 120 to supply the electrical power generated by the PV power plant 120 determined at 412 to the electrical load and demands the BESS 170 to contribute towards supplying the electrical power shortfall. The dispatch module 226 determines if the BESS 170 can supply the electrical power shortfall at a later stage in the method 400 (discussed below with respect to sub-process 800).

The dispatch module 226 records the operating status of the PV power plant 120, the electrical power supplied to the electrical load 10 by the PV power plant 120, the electrical power shortfall, and that the BESS 170 has been demanded to contribute towards supplying the electrical power shortfall for the weather data point. For example, this information may be defined in the PV operation record relating to the weather data point defined by the PV operation table stored on the data store 214 as discussed above in [0195].

At 628, the dispatch module 226 issues a demand to the combustion module 220 to start-up the combustion power plant 160. At this point, the dispatch module 226 has completed the sub-process 600 and processing proceeds to step 424 of the method 400 (see FIG. 7).

At 630, the dispatch module 226 utilises (i.e. dispatches) the combustion power plant 160 to supply the electrical demand to the electrical load 10.

At 632, the dispatch module 226 determines that the electrical power generated by the PV power plant 120 determined at 412 is excess electrical power. The dispatch module 226 determines if the excess electrical power is to be added to the state of charge of the BESS 170 (i.e. to simulate charging of the BESS 170) at a later stage in the method 400 (discussed below with respect to sub-process 800).

The dispatch module 226 records the operating status of the PV power plant 120, that the combustion power plant 160 provided the electrical demand to the electrical load 10, and the excess electrical power in the data store 214. For example, this information may be defined in the PV operation record relating to the weather data point defined by the PV operation table stored on the data store 214 as discussed above in [0195]. At this point, the dispatch module 226 has completed the sub-process 600 and processing proceeds to step 424 of the method 400 (see FIG. 7).

At 634, the dispatch module 226 determines that the PV power plant is not operating (e.g. because it is night time). The PV module 216 records the operating status of the PV power plant 120 in the data store 214. For example, this information may be defined in the PV operation record relating to the weather data point defined by the PV operation table stored on the data store 214 as discussed above in [0195]. At this point, the dispatch module 226 has completed the sub-process 600 and processing proceeds to step 424 of the method 400 (see FIG. 7).

Once the dispatch module 226 determines the operating status of the PV power plant 120 for the weather data point, processing proceeds to step 424 of the method 400 (see FIG. 7).

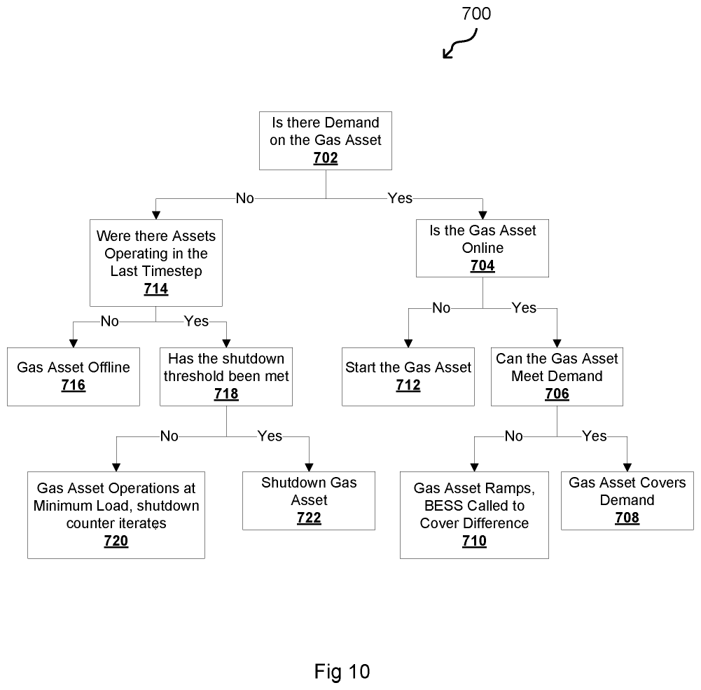

At 424, the dispatch module 226 determines the operational status of the combustion power plant 160 for the weather data point. To determine the operational status of the combustion power plant 160 for the weather data point, the dispatch module 226 performs sub-process 700 (see FIG. 10).

At 702, the dispatch module 226 determines if there is a demand on the combustion power plant 160 based on the operating status of the PV power plant 120 determined at 422 and the operating status of the CSP generator 130 determined at 420. The operating status of the PV power plant 120 includes data as to whether or not the dispatch module 226 has demanded the combustion power plant 160 to generate and supply electrical power to the electrical load 10. If the dispatch module 226 determines that there is a demand for the combustion power plant 160, the dispatch module 226 proceeds to step 704. If the dispatch module 226 determines that there is no demand for the combustion power plant 160, the dispatch module 226 proceeds to step 714.

At 704, the dispatch module 226 determines if the combustion power plant 160 was operating, starting-up, or ramping-up in the previous processed weather data point based on the operating status of the combustion power plant 160 determined for the previous processed weather data point. If so, the dispatch module 226 proceeds to step 706. If not, the dispatch module 226 proceeds to step 712.

At 706, the dispatch module 226 retrieves the electrical power demanded from the combustion power plant 160, determines the electrical power output of the combustion plant 160 for the previous processed weather data point, and determines if the combustion power plant 160 can supply the electrical power demanded of it. The electrical supply demanded of the combustion power plant is to supply the electrical power shortfall determined at 620, the entire electrical demand determined at 630, or the electrical power shortfall when the PV power plant is not operating (i.e. because it is night time) and the CSP plant 130 is unable to meet the electrical demand to the electrical load 10.

In response to determining that the combustion power plant 160 (or one or more combustion generators comprising the combustion power plant 160) was operating for the previous processed weather data point, the dispatch module 226 determines that the combustion power plant 160 can supply the electrical power demanded of it for the weather data point and proceeds to step 708.

In response to determining that the combustion power plant 160 (or one or more combustion generators comprising the combustion power plant 160) is starting-up or ramping up, the dispatch module 226 determines that the combustion power plant 160 is unable to supply the electrical power demanded of it for the weather data point and proceeds to step 710.

The dispatch module 226 determines if the operating status of the combustion power plant 160 (or one or more combustion generators comprising the combustion power plant 160) changes from starting-up to ramping-up based on how many consecutive previous weather data points indicate the status of the combustion power plant 160 as starting-up. The dispatch module 226 determines the period of time the combustion power plant 160 has been starting-up for based on the number of consecutive previous processed weather data points indicating the status of the combustion power plant 160 as starting-up. If this period of time is greater than the start-up time of the combustion power plant 260, the dispatch module 226 updates the status of the combustion power plant 160 from starting-up to ramping-up. If this period of time is less than the start-up time of the combustion power plant 160, the dispatch module 226 retains the status of the combustion power plant 160 as starting-up.

The period of time that the combustion power plant 160 (or one or more combustion generators comprising the combustion power plant 160) will have a status of ramping-up is based on the electrical power demanded of the combustion power plant 160 and the ramp rate of the combustion power plant 160. For each weather data point where the status of the combustion power plant 160 is ramping-up, the electrical power output of the combustion power plant 160 for the weather data point is calculated by based on the electrical power output of the combustion power plant 160 from the previous processed weather data point and the ramp rate of the combustion power plant 160. The dispatch module 226 determines that the combustion power plant 160 is no longer ramping-up once the electrical power output of the combustion power plant 160 equals the electrical power demanded of it. At this point, the dispatch module 226 updates the status of the combustion power plant 160 from ramping-up to operating.

At 708, for the weather data point, the dispatch module 226 utilises (i.e. dispatches) the combustion power plant 160 to supply the electrical power demanded of it (i.e. the electrical power shortfall determined at 620, the entire electrical demand determined at 630, or because the CSP plant 130 is offline or is unable to meet the electrical demand).

The dispatch module 226 records that the combustion power plant 160 is operating for the weather data point and the electrical power delivered to the electrical load 10 by the combustion power plant 160 in the data store 214. For example, the dispatch module 226 may record the operational status of the combustion power plant 160 determined at 708 and the power delivered by the combustion power plant 160 to the electrical load 10 for the weather data point in a combustion operation record defined by a combustion operation table stored in the data store 214. An example combustion operation table may define the following:

| | | | | | | |
|---|---|---|---|---|---|---|
| Weather | Time | Status of | Power supplied by | Previous | Time since | Demand on |
| data point | stamp | combustion | combustion power | start-up | previous | BESS 170 to |
| | | power plant 160 | plant 10 | time | shutdown | provide electrical |
| | | | | | | power |

At this point, the dispatch module 226 has completed the sub-process 700 and processing proceeds to step 426 of the method 400 (see FIG. 7).

At 710, the dispatch module 226 determines the difference between the electrical demand and the combined electrical power output of the PV power plant 120 and the combustion power plant 160 for the weather data point and demands the BESS 170 to supply this difference. In response to determining that the combustion power plant 160 is starting-up at 706, the dispatch module 226 determines the electrical power to be delivered by the BESS 170 by subtracting the electrical power generated by the PV power plant 120 from the electrical demand. In response to determining that the combustion power plant 160 is ramping-up, the dispatch module 226 determines the electrical power to be delivered by the BESS 170 by subtracting the combined electrical power output of the PV power plant 120 and the combustion power plant 160 (i.e. as it is ramping-up) for the weather data point from the electrical demand.

The dispatch module 226 determines if the BESS 170 can supply the electrical power demanded of it at a later stage in the method 400 (discussed below with respect to sub-process 800). The dispatch module 226 records the operating status of the combustion power plant 160 and that the BESS 170 has been demanded to supply the electrical power demanded of the combustion power plant 160 for the weather data point in the data store 214. For example, this information may be defined in the combustion operation record relating to the weather data point defined by the combustion operation table stored on the data store 214 as discussed above in [0225]. At this point, the combustion module 220 has completed the sub-process 700 and processing proceeds to step 426 of the method 400 (see FIG. 7).

At 712, the dispatch module 226 demands the combustion power plant 160 to start-up. The dispatch module 226 records the operating status of the combustion power plant 160 (i.e. starting-up) for the weather data point in the data store 214. For example, this information may be defined in the combustion operation record relating to the weather data point defined by the combustion operation table stored on the data store 214 as discussed above in [0225]. At this point, the dispatch module 226 has completed the sub-process 700 and processing proceeds to step 426 of the method 400 (see FIG. 7).

At 714, the dispatch module 226 determines if the status of the combustion power plant 160 was operating, starting-up, shutting down, or spinning reserve in the previous processed weather data point based on the operating status of the combustion power plant 160 determined for the previous processed weather data point. If not, the dispatch module 226 proceeds to step 716. If so, the dispatch module 226 proceeds to step 718.

At 716, the dispatch module 226 determines that the combustion power plant 160 is not operating. The dispatch module 226 records the operating status of the combustion power plant 160 (i.e. not operating/offline) for the weather data point in the data store 214. For example, this information may be defined in the combustion operation record relating to the weather data point defined by the combustion operation table stored on the data store 214 as discussed above in [0225]. At this point, the dispatch module 226 has completed the sub-process 700 and processing proceeds to step 426 of the method 400 (see FIG. 7).

At 718, the dispatch module 226 determines if the shutdown time for the combustion power plant 160 has been reached. Alternatively, if the combustion power plant 160 comprises multiple combustion generators, the dispatch module 226 determines if the shutdown time for one or more of the combustion generators has been reached. If not, the dispatch module 226 proceeds to step 720. If so, the dispatch module 226 proceeds to 722.

The dispatch module 226 determines if the shutdown threshold for the combustion power plant 160 (or one or more combustion generators comprising the combustion power plant 160) has been reached based on how many consecutive previous weather data points indicate the status of the combustion power plant 160 as shutting down. The dispatch module 226 determines the period of time the combustion power plant 160 (or one or more combustion generators) has been shutting down for based on the number of consecutive previous processed weather data points indicating the status of the combustion power plant 160 (or one or more combustion generators) as shutting down. If this period of time is greater than the shutdown time of the combustion power plant 160 (or one or more combustion generators), the (or one or more combustion generators) determines that the shutdown time for the combustion power plant 160 (or one or more combustion generators) has been reached. If this period of time is less than the shutdown of the combustion power plant 160 (or one or more combustion generators), the (or one or more combustion generators) determines that shutdown time has not been reached.

At 720, the dispatch module 226 determines that the combustion power plant 160 (or one or more combustion generators) has not shut down for the weather data point. The dispatch module 226 records the operating status of the combustion power plant 160 (or one or more combustion generators) as shutting down/spinning reserve for the weather data point in the data store 214. For example, this information may be defined in the combustion operation record relating to the weather data point defined by the combustion operation table stored on the data store 214 as discussed above in [0225]. At this point, the dispatch module 226 has completed the sub-process 700 and processing proceeds to step 426 of the method 400 (see FIG. 7).

At 722, the dispatch module 226 shuts down the combustion power plant 160 (or one or more combustion generators comprising the combustion power plant 160) for the weather data point. The dispatch module 226 records the operating status of the combustion power plant 160 (i.e. shutdown/not operating/offline) for the weather data point in the data store 214. For example, this information may be defined in the combustion operation record relating to the weather data point defined by the combustion operation table stored on the data store 214 as discussed above in [0225]. At this point, the dispatch module 226 has completed the sub-process 700 and processing proceeds to step 426 of the method 400 (see FIG. 7).

Once the dispatch module 226 determines the operating status of the combustion power plant 160 for the weather data point, processing proceeds to step 426 of the method 400 (see FIG. 7).

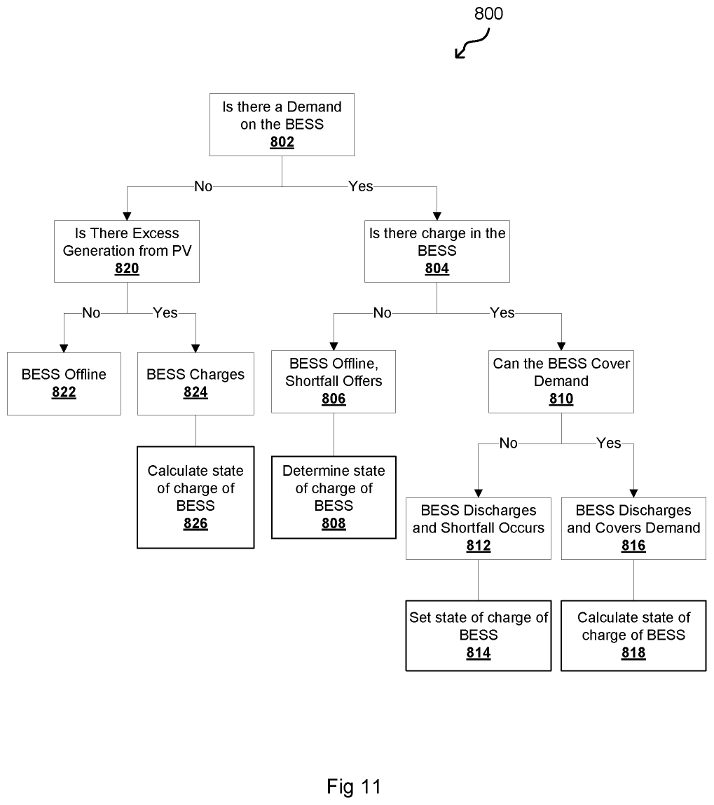

At 426, the dispatch module 226 determines the operational status of the BESS 170 for the weather data point. To determine the operational status of the BESS 170 for the weather data point, the dispatch module 226 performs sub-process 800 (see FIG. 11).

At 802, the dispatch module 226 determines if there is a demand on the BESS 170 based on the operating status of the PV power plant 120 determined at 422 and the operating status of the combustion power plant 160 determined at 424. The operating status of the PV power plant 120 and the operating status of the combustion power plant 160 includes data as to whether or not the dispatch module 226 has demanded the BESS 170 to supply electrical power to the electrical load 10. If the dispatch module 226 determines that there is a demand for the BESS 170, the dispatch module 226 proceeds to step 804. If the dispatch module 226 determines that there is no demand for the BESS 170, the dispatch module 226 proceeds to step 820.

At 804, the dispatch module 226 determines if the state of charge of the BESS 170 is at or above the maximum depth of discharge for the BESS 170 based on the state of charge of the BESS 170 determined for the previous processed weather data point. If not, the dispatch module 226 proceeds to step 806. If so, the dispatch module 226 proceeds to step 810.

At 806, the dispatch module 226 determines that the BESS 170 cannot provide the electrical power demanded of it and that the hybrid electrical power plant 100 is unable to supply electrical load 10 with the electrical demand for the weather data point. The electrical power demanded of the BESS 170 may be the electrical power shortfall determined at 618, the electrical demand determined at 626, or the electrical power demanded of the combustion power plant 160 determined at 710.

The dispatch module 226 determines that the electrical power delivered to the electrical load 10 is the electrical power generated by the PV power plant 120 determined at 412 and the electrical power generated by the combustion power plant 160 for the weather data point. The dispatch module 226 determines the shortfall in electrical demand to the electrical load 10 for the weather data point by subtracting the electrical power supplied by the PV power plant 120 and the electrical power supplied by the combustion power plant 160 for the weather data point from the electrical demand.

At 808, for the weather data point, the dispatch module 226 sets the state of charge of the BESS 170 to the state of charge of the BESS determined for the previous processed weather data point calculates the state of charge of the BESS 170.

The dispatch module 226 records that the BESS 170 the operating status of the BESS 170 (i.e. charging) and the state of charge of the BESS 170 for the weather data point in the data store 214. For example, the dispatch module 226 may record the operational status of the BESS determined at 808 and the state of charge of the BESS 170 for the weather data point in a BESS operation record defined by a BESS operation table stored in the data store 214. An example BESS operation table may define the following:

| | | | | | | |
|---|---|---|---|---|---|---|
| Weather | Time | Status of | Power supplied | Shortfall in | State of charge | Lost |
| data point | stamp | BESS 170 | by BESS 170 | electrical demand | of BESS 170 | electrical |
| | | | | | | power |

At this point, the dispatch module 226 has completed the sub-process 800 and processing proceeds to step 428 of the method 400 (see FIG. 7).

At 810, the dispatch module 226 determines if the BESS 170 can supply the electrical power demanded of it based on the state of charge of the BESS 170 determined for the previous processed weather data point. The electrical power demanded of the BESS 170 may be the electrical power shortfall determined at 618, the electrical demand determined at 626, or the electrical power demanded of the combustion power plant 160 determined at 710. If not, the dispatch module 226 proceeds to step 812. If so, the dispatch module 226 proceeds to step 816.

At 812, the dispatch module 226 determines the maximum amount of electrical power the BESS 170 can supply to the electrical load 10 for the weather data point (i.e. the maximum BESS electrical power supply). The dispatch module 226 determines the maximum BESS electrical power supply for the weather data point as the difference between the state of charge of the BESS 170 determined for the previous processed weather data point and the maximum depth of discharge for the BESS 170. The dispatch module 226 utilises (i.e. dispatches) the BESS 170 to supply the maximum BESS electrical power supply to the electrical load 10.

At 814, the dispatch module 226 sets the state of charge for the BESS 170 to the maximum depth of discharge for the weather data point.

The dispatch module 226 also determines the shortfall in electrical supply to the electrical load 10. The dispatch module 226 determines the shortfall in electrical supply by subtracting the electrical power supplied by the PV power plant 120 determined at 412 and the maximum BESS electrical power supply determined at 812 from the electrical demand.

The dispatch module 226 records the operating status of the BESS 170 (i.e. discharged) for the weather data point in the data store 214, the state of charge of the BESS 170, and the shortfall in electrical power supply for the weather data point in the data store 214. For example, this information may be defined in the BESS operation record relating to the weather data point defined by the BESS operation table stored on the data store 214 as discussed above in [0243]. At this point, the dispatch module 226 has completed the sub-process 800 and processing proceeds to step 428 of the method 400 (see FIG. 7).

At 816, the dispatch module 226 utilises (i.e. dispatches) the BESS 170 to supply the electrical power demanded of it.

At 818, the dispatch module 226 determines the amount of energy consumed from the BESS 170 to supply the electrical power demanded of it to the electrical load 10, taking into account efficiency losses in the BESS 170 supplying the electrical load with electrical power. This efficiency information may form part of the BESS operating data received at 402.

The dispatch module 226 calculates the state of charge of the BESS 170 for the weather data point. To determine the state of charge of the BESS 170 for the weather data point, the dispatch module 226 subtracts the energy consumed from the BESS 170 determined at 818 from the state of charge of the BESS 170 determined for the previous processed weather data point.

The dispatch module 226 records the operating status of the BESS 170 (i.e. discharging), the state of charge of the BESS 170, the electrical power supplied to the electrical load by the BESS 170, and any lost electrical power for the weather data point in the data store 214. For example, this information may be defined in the BESS operation record relating to the weather data point defined by the BESS operation table stored on the data store 214 as discussed above in [0243]. At this point, the dispatch module 226 has completed the sub-process 800 and processing proceeds to step 428 of the method 400 (see FIG. 7).

At 820, the dispatch module 226 determines if there is any excess electrical power generated by the PV power plant 120 determined at 612. If not, the dispatch module 226 proceeds to step 822. If so, the dispatch module 226 proceeds to step 824.

At 822, for the weather data point, the dispatch module 226 determines that the BESS 170 is not operating (i.e. offline) and determines that the state of charge of the BESS 170 is the state of charge of the BESS 170 determined for the previous processed weather data point. The dispatch module 226 records the operating status of the BESS 170 (i.e. offline) and the state of charge of the BESS 170 for the weather data point in the data store 214. For example, this information may be defined in the BESS operation record relating to the weather data point defined by the BESS operation table stored on the data store 214 as discussed above in [0243]. At this point, the dispatch module 226 has completed the sub-process 800 and processing proceeds to step 428 of the method 400 (see FIG. 7).

At 824, the dispatch module 226 utilises (i.e. dispatches) the PV power plant 120 to charge the BESS 170.

At 826, the dispatch module 226 calculates the state of charge of the BESS 170 for the weather data point. To determine the state of charge of the BESS 170 for the weather data point, the dispatch module 226 adds the excess electrical power generated by the PV power plant 120 determined at 612 (less any efficiency losses due to charging the BESS 170) to the state of charge of the BESS 170 determined for the previous processed weather data point.

The dispatch module 226 determines if this calculation is greater than the maximum state of charge of the BESS 170. If not, the dispatch module 226 sets the result of this calculation as the state of charge of the BESS 170 for the weather data point and records this in the data store 214.

If the result of this calculation is greater than the maximum state of charge of the BESS 170, the dispatch module 226 only adds a portion of the excess electrical power generated by the PV power plant 120 determined at 632 to bring the state of charge of the BESS 170 to the maximum state of charge of the BESS 170. In this case, for the weather data point, the dispatch module 226 sets the state of charge of the BESS 170 to the maximum state of charge of the BESS 170, calculates the amount of the excess electrical power generated by the PV power plant 120 not added to the BESS 170 (i.e. lost electrical power), and records this in the data store 214.

The dispatch module 226 records the operating status of the BESS 170 (i.e. charging), the state of charge of the BESS 170, and any lost electrical power for the weather data point in the data store 214. For example, this information may be defined in the BESS operation record relating to the weather data point defined by the BESS operation table stored on the data store 214 as discussed above in [0243]. At this point, the dispatch module 226 has completed the sub-process 800 and processing proceeds to step 428 of the method 400 (see FIG. 7).

Once the dispatch module 226 determines the operating status of the BESS 170 for the weather data point, processing proceeds to step 428 of the method 400 (see FIG. 7).

At 428, the server application 212 determines if the weather data point is the last weather data point to be processed. If so, the server application 212 proceeds to step 430. If not, the server application 212 returns to step 416 to retrieve and begin processing the next chronological weather data point.

The server application 212 may initially set the status of each weather data point to “unprocessed” and then update the status of the weather data point to “processed”. Accordingly, the server application 212 may determine the next chronological weather data point based in the status and time stamps of the weather data points.

At 430, the server application 212 generates an output of the simulation of the hybrid electrical power generation system 100 and communicates the output to the user. For example, the simulation application 212 communicate the output as a user interface displayed on the display 318 of the user device 230 or as data file (e.g. a spreadsheet, text file, etc.) attached to any suitable communication means (e.g. email).

The output may include the operating status of the PV power plant 120, the operating status of CSP plant 130, the operating status of combustion power plant 160, the operating status of BESS 170, the electrical power supplied to the electrical load 10, any shortfall in the electrical power supply to the electrical load 10, any lost thermal energy, and any lost electrical energy determined for each weather data point. The output may also include:
the total shortfall hours—the number of hours the hybrid electrical power generation system 100 does not meet the electrical demand);
the total shortfall (MWh)—the total shortfall over the simulation;
Shortfall due to the BESS 170 being discharged;
PV gross generation (MWh)—the total gross output of the PV power plant 120 over the simulation;
CSP gross generation (MWh)—the total gross output of the CSP plant 130 over the simulation;
Combustion gross generation (MWh)—the total gross output of the combustion power plant 160 over the simulation;
BESS gross contribution (MWh)—the total gross output of the BESS 170 over the simulation; and
Shortfall due to combustion power plant 160 (or one of the combustion generators of the combustion power plant 160) ramping up to the electrical power output demanded of it.

Based on the output, the user may be able to optimise certain components of the hybrid electrical power generation system 100 in order to reduce the shortfall in electrical supply, any lost thermal energy, and any lost electrical power. The user can then use the simulation tool to simulate the optimised hybrid electrical power generation system 100.

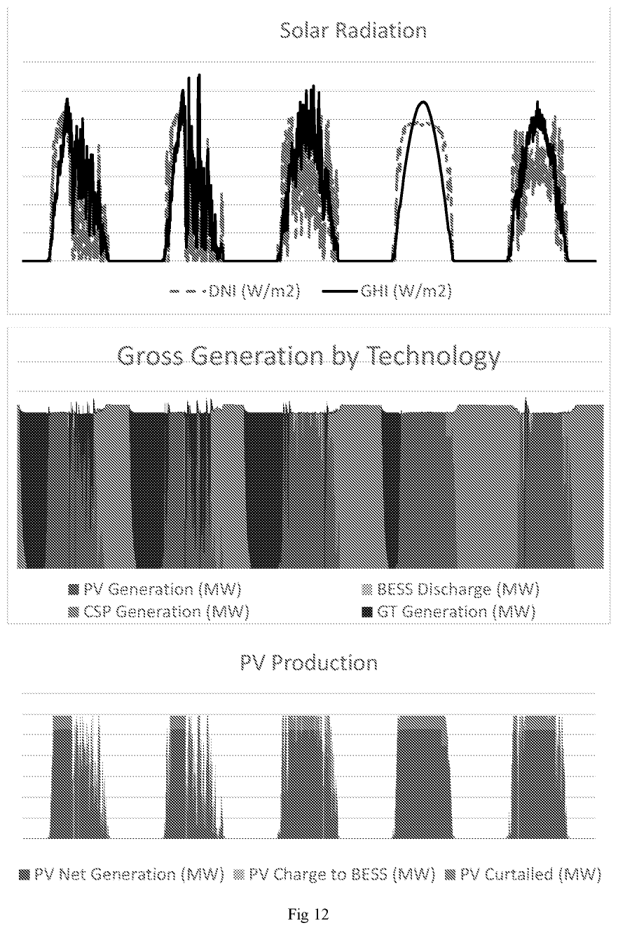

FIG. 12 is an example of an output generated from the simulation tool having three graphs (i.e. a top, middle, and bottom graph). The top graph illustrates the solar irradiance over a period of several days for the location at which the hybrid electrical power generation system is to be installed. The middle graphs illustrates which of the PV power plant 120, the CPS plant 130, the combustion power plant 160, and the BESS 170 are supplying electrical power to the electrical load 10 over this period. The bottom graphs illustrates the electrical power generated by the PV power plant 120 over this period.

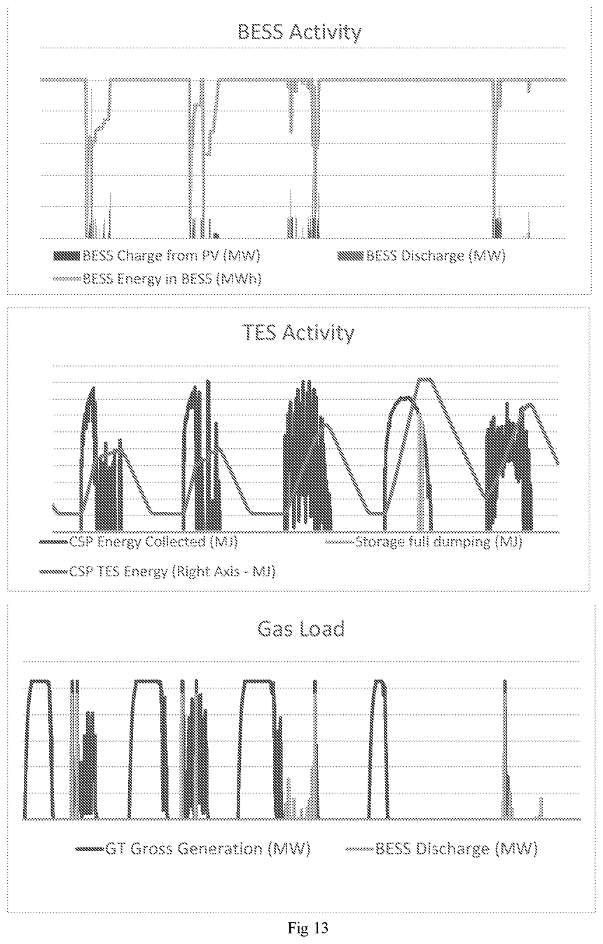

FIG. 13 is another example of an output generated from the simulation tool having three graphs (i.e. a top, middle, and bottom graph). The top graph illustrates the activity of the BESS 170 (e.g. charging or discharging) over a period of several days, the middle graph illustrates the activity of the TESS 133 over this period, and the bottom graph illustrates the electrical power output of the combustion power plant 160 over this period.

Although particular modules of the server application 212 have been described above as performing particular method steps and/or operations, these method steps and/or operations could, however, be performed by an alternative module or application running on the simulation server system 210 or a separate system.

In the embodiment described above, the method 400 depicted in FIG. 8 is a simulation of the hybrid electrical power generation system 100 that utilises two different renewable energy (RE) power generation technologies: a single type variable renewable energy (VRE) power plant (i.e. an intermittent power generation technology) in the form of the PV power plant 120; and a dispatchable RE power plant in the form of the CSP plant 130. It will be appreciated that, in alternative embodiments, the general principles underpinning the method 400 may be applied to methods of simulating other hybrid electrical power generation systems that utilise various combinations of differing RE power generation technologies with the combustion power plant 160, as described above in paragraph [0098].

In one modification of the method 400 described above, the hybrid electrical power generation system 1100 depicted in FIG. 4 could be simulated in which a dispatchable RE power plant (CSP plant 1130) is combined with a mixed type VRE power plant 1150 that comprises a combination of different types of VRE generation technologies (one or more wind turbines 1115 and at least one PV power plant 1120). Such a method of simulation would be substantially identical to the method 400 described above, with a number of minor variations to account for the inclusion of the one or more wind turbines 1115 and the resulting modification of the VRE power plant from a single type VRE power plant to the mixed type VRE power plant 1150.

For example, the server application could include a wind module that, as part of step 402, could receive wind turbine operating data relating to the one or more wind turbines 1115 at step 402. As described above at paragraph [0115], the wind module and the PV module could be combined within a single VRE module, or alternatively configured as standalone modules in the server application. Step 412 could include the wind module calculating the potential electrical power generated by the one or more wind turbines 1115. The wind module could store this potential electrical power generated for each weather data point in a data store, e.g. in a PV, Wind and CSP simulation record defined by a PV, Wind and CSP simulation table similar to that depicted above in paragraph [0147]. Alternatively, the VRE module could store the combined potential electrical power generated by the one or more wind turbines 1115 and the at least one PV power plant 1120 for each weather data point in the data store, e.g. in a VRE and CSP simulation record defined by a VRE and CSP simulation table. Accordingly, for ease of modelling, steps 418, 420 and 422, along with sub-processes 500, 600 and 700, could model the mixed type VRE power plant 1150 as a single power generation unit. This could involve replacing any reference to ‘the PV power plant’ with the ‘VRE power plant’. Alternatively, steps 418, 420 and 422, along with sub-processes 500, 600 and 700, could model the one or more wind turbines 1115 and the at least one PV power plant 1120 as separate power generation units, with appropriately determined logic.

In other modifications, the method 400 described above could be adapted to simulate hybrid electrical power generation systems that utilise either a VRE power plant (which could be single or mixed type) or a dispatchable RE power plant, but not a combination of these VRE and dispatchable RE power generation technologies.

For example, the CSP plant 130 and 1130 could be omitted from the hybrid electrical power generation systems 100 and 1100 depicted in FIGS. 1 and 4. The server application could omit the CSP module, as there would not be any CSP operating data to receive as part of step 402, and the remainder of method 400 could be adapted to simulate such a hybrid electrical power generation system substantially by omitting or skipping steps 414 and 420. Omitting or skipping step 414 would modify step 418 to retrieve only CSP power. Similarly, by omitting or skipping step 420, the adapted method would also omit or skip sub-process 500, along with steps 614 and 622 of sub-process 600: if the dispatch module determines at step 606 that the electrical power generated by the VRE power plant is not able to supply the electrical demand to the electrical load, the dispatch module 226 proceeds to step 616.

Alternatively, the VRE plant (PV plant 130 of system 100 and the one or more wind turbines 1115 and the at least one PV power plant 1120 of system 1100) could be omitted from the hybrid electrical power generation systems 100 and 1100 depicted in FIGS. 1 and 4. The server application could omit the PV/VRE/wind module, as there would not be any PV/VRE/wind operating data to receive as part of step 402, and step 412 could be omitted or skipped (with the consequential modification to step 418). Whilst step 422 also could be omitted or skipped, it may not be entirely necessary to omit or skip sub-process 600. Rather, the steps below step 604 of sub-process 600 (apart from steps 614 and 622) could be modified for use with the CSP plant and used to replace steps 520 and below of sub-process 500. Such a modification and replacement could result in steps 516 and 518 leading to the question of “Is the CSP secure”? If not, the method could proceed to step 624 (with the result of step 632 being the CSP charging the BESS). If so, and the CSP plant can cover demand, then the CSP plant could be dispatched to the load (e.g. equivalent to steps 606, 608 and 610), with any excess being used to charge the BESS (e.g. equivalent to step 612). If so, and the CSP plant cannot cover demand, then the combustion plant could cover the shortfall if it is on (e.g. equivalent to steps 616 and 620), or the BESS could cover the shortfall if the combustion plant is not on (e.g. equivalent to steps 616 and 618). When carrying out sub-process 800 at step 426, the determination at step 820 could be if there is any excess electrical power generated by the CSP plant.

### Method of Operating Hybrid Electrical Power Generation System 100

### Operating Hybrid Electrical Power Generation System 100 Using Forecasted Weather Data

The hybrid electrical power generation system 100 may be constructed based on the simulation. The controller 110 is configured to operate the constructed hybrid electrical power generation system 100 according to the method 400 and sub-processes 500-800 discussed above. Accordingly, the controller 110 is configured to perform the methods and operations described above for each of the PV module 216, CSP module 218, combustion module 220, BESS module 222, and dispatch module 226. However, instead of using a historical weather dataset, the controller 110 uses a combination of a current and forecasted weather dataset having a plurality of current and forecasted data points to perform a forecast simulation of the hybrid electrical power generation system 100 to determine if it will be able to supply the electrical load 10 with the electrical demand at a future time. Based on the result of this simulation, the controller 110 will be able to control dispatch of the PV power plant 120, the CSP plant 130, the combustion power plant 160, and the BESS 170 in order to supply the electrical load 10 with the electrical demand.

For the forecast simulation, the current thermal energy in the hot energy storage tank 138 and the current state of charge of the BESS 170 are used as the starting values of the corresponding components in the simulation. Further, the current operating status of the PV power plant 120, the CSP plant 130, the combustion power plant 160, and the BESS 170 are used for the operating statuses of the corresponding components in the forecast simulation. The controller 110 can then simulate the hybrid electrical power generation system 100 using the method discussed above and the forecasted weather dataset to determine if the hybrid electrical power generation system 100 will be able to supply the electrical load 10 with the electrical demand at the future time.

If the controller determines that the hybrid electrical power generation system 100 cannot supply the demand for the future time based forecast simulation, the controller 110 may ignore the dispatch priority order and start-up the combustion power plant 160 in order to reduce or prevent any electrical power shortfall.

### Operating Hybrid Electrical Power Generation System 100 Using Instantaneous Operational Data

Alternatively, the controller 110 may dispatch the PV power plant 120, the CSP plant 130, the combustion power plant 160, and/or the BESS 170 according to method 400, sub-process 500, sub-process 600, sub-process 700, and/or sub-process 800 using the current thermal energy in the hot energy storage tank 138, the current state of charge of the BESS 170, the current operating status of the PV power plant 120, the current operating status of the CSP plant 130, the current operating status of the combustion power plant 160, and the current operating status of the BESS 170. This data is periodically updated at short (one minute or less) intervals, and may be used in combination with forecast data. In one embodiment, the forecast data is used to modify the operation of the controller 110. For example, if the forecast data includes unbroken sunshine for the next 8 hours with a high reliability factor, this may be used to override or forego the requirement that the state of charge of the BESS 170 be at or above the secure level 176 and capable of supplying the electrical demand during the start-up time of the combustion power plant 160. The PV power plant 120 can then be used to supply power rather than charging the BESS 170 to the secure level 176.

In the embodiments described above, the operation methods are applied to the hybrid electrical power generation system 100 that utilises two different renewable energy (RE) power generation technologies: a single type variable renewable energy (VRE) power plant (i.e. an intermittent power generation technology) in the form of the PV power plant 120; and a dispatchable RE power plant in the form of the CSP plant 130. It will be appreciated that, in alternative embodiments, as was the case for the previously described simulation methods, the general principles underpinning these operating methods may be applied to methods of operating other hybrid electrical power generation systems that utilise various combinations of differing RE power generation technologies with the combustion power plant 160, as described above in paragraph [0098].

It will be understood that the invention disclosed and defined in this specification extends to all alternative combinations of two or more of the individual features mentioned or evident from the text or drawings. All of these different combinations constitute various alternative aspects of the invention.

1. A method of operating a hybrid electrical power generation system to supply an electrical demand, the hybrid electrical power generation system having a battery energy storage system (BESS), a renewable energy (RE) power plant, and a combustion power plant having a supply delay, the supply delay being a time associated with signalling the combustion power plant to start-up to the combustion power plant being configured for supplying the electrical demand, the method comprising:
determining a state of charge of the BESS;
in response to determining that the RE power plant is generating electrical power and the state of charge of the BESS is at least at a secure level: dispatching the RE power plant to supply at least some of the electrical demand; and
in response to determining that the RE power plant is generating electrical power and the state of charge of the BESS is at an insecure level: dispatching the RE power plant to charge the BESS,
wherein the secure level is a minimum state of charge of the BESS that is configured for supplying at least a substantial portion of the electrical demand during the supply delay; and
wherein the insecure level is a state of charge of the BESS that is less than the secure level

2. The method of claim 1, wherein the RE power plant comprises a variable renewable energy (VRE) power plant.

3. The method of claim 2, further comprising:
in response to determining that the VRE power plant is generating electrical power and the state of charge of the BESS is at least at the secure level:
dispatching the VRE power plant to supply the electrical demand if the electrical power generated by the VRE power plant is configured for supplying the electrical demand; or
dispatching the BESS to supply at least some of the electrical demand and dispatching the VRE power plant to supply at least some of the electrical demand if the electrical power generated by the VRE power plant is not configured for supplying the electrical demand and a combustion generator is not operating.

4. The method of claim 2, further comprising starting the combustion power plant in response to determining that the VRE power plant is generating electrical power, the state of charge of the BESS is at the insecure level, and the combustion power plant is not operating.

5. The method of claim 2, further comprising, in response to determining that the VRE power plant is generating electrical power, the state of charge of the BESS is at least at the secure level, and the electrical power generated by the VRE power plant is in excess of the electrical demand:
dispatching the VRE power plant to supply the electrical demand; and
charging the BESS with the electrical power generated by the VRE power plant.

6. The method of claim 2, further comprising, in response to determining that the VRE power plant is generating electrical power, the state of charge of the BESS is at the insecure level, and a combustion generator is operating:
dispatching the combustion generator to supply the electrical demand; and
charging the BESS with the electrical power generated by the VRE power plant.

7. The method of claim 2, wherein the VRE power plant comprises at least one photovoltaic (PV) power plant and/or at least one wind turbine power plant.

8. The method of claim 2, wherein the hybrid electrical power generation system further comprises a concentrating solar thermal power (CSP) plant and the method further comprises, in response to determining that the VRE power plant is generating electrical power and the state of charge of the BESS is at least at the secure level:
dispatching the BESS to supply at least some of the electrical demand and dispatching the VRE power plants to supply at least some of the electrical demand if the electrical power generated by the VRE power plant is not configured for supplying the electrical demand and the CSP plant and a combustion generator are not operating.

9. The method of claim 8, further comprising, in response to determining that the VRE power plant is generating electrical power and the state of charge of the BESS is at least at the secure level:
dispatching the combustion generator to supply at least some of the electrical demand and dispatching the VRE power plant to supply at least some of the electrical demand if the electrical power generated by the VRE power plant is not configured for supplying the electrical demand and the combustion generator is operating.

10. The method of claim 8, further comprising, in response to determining that the VRE power plant is generating electrical power and the state of charge of the BESS is at least at the secure level:
dispatching the CSP plant to supply at least some of the electrical demand and dispatching the VRE power plant to supply at least some of the electrical demand if the electrical power generated by the VRE power plant of not configured for supplying the electrical demand and the CSP plant is operating.

11. The method of claim 1, wherein the RE power plant comprises a concentrating solar thermal power (CSP) plant.

12. The method of claim 11, further comprising, in response to determining that the CSP plant is not operating, the state of charge of the BESS is at the insecure level and the CSP plant has received instructions to start-up:
charging the BESS with the electrical power generated by at least one power plant of the hybrid electrical power generation system; and
deferring dispatch of the CSP plant to supply at least some of the electrical demand until the state of charge of the BESS is at the secure level.

13. A hybrid electrical power generation system for supplying an electrical demand, comprising:
a renewable energy (RE) power plant;
a combustion generator having a supply delay, the supply delay being a time associated with signalling a combustion power plant to start-up to the combustion power plant being configured for supplying the electrical demand;
a battery energy storage system (BESS); and
a controller configured to dispatch the RE power plant, the combustion generator, and the BESS to supply the electrical demand, wherein, in response to determining that the RE power plant is generating electrical power and a state of charge of the BESS is at least at a secure level, the controller is configured to:
dispatch the RE power plant to supply at least some of the electrical demand; and
in response to determining that the RE power plant is generating electrical power and the state of charge of the BESS is at an insecure level, the controller is configured to: dispatch the RE power plant to charge the BESS, wherein the secure level is a minimum state of charge of the BESS that is configured for supplying at least a substantial portion of the electrical demand during the supply delay; and wherein the insecure level is a state of charge of the BESS that is less than the secure level

14. The hybrid electrical power generation system of claim 13, wherein the RE power plant comprises a variable renewable energy (VRE) power plant.

15. The hybrid electrical power generation system of claim 14, wherein the controller is configured to:
in response to determining that the VRE power plant is generating electrical power and the state of charge of the BESS is at least at the secure level:
dispatch the VRE power plant to supply the electrical demand if the electrical power generated by the VRE power plant is configured for supplying the electrical demand; or
dispatch the BESS to supply at least some of the electrical demand and dispatching the VRE power plant to supply at least some of the electrical demand if the electrical power generated by the VRE power plant is not configured for supplying the electrical demand and a combustion generator is not operating.

16. The hybrid electrical power generation system of claim 14, wherein the VRE power plant comprises at least one photovoltaic (PV) power plant and/or at least one wind turbine power plant.

17. The hybrid electrical power generation system of claim 14, further comprising a concentrating solar thermal power (CSP) plant, wherein, in response to determining that the VRE power plant is generating electrical power and the state of charge of the BESS is at least at the secure level, the controller is configured to:
dispatch the BESS to supply at least some of the electrical demand and dispatch the VRE power plant to supply at least some of the electrical demand if the electrical power generated by the VRE power plant is not configured for supplying the electrical demand and the CSP plant and the combustion generator are not operating.

18. The hybrid electrical power generation system of claim 17, wherein the controller is configured to:
in response to determining that the VRE power plant is generating electrical power and the state of charge of the BESS is at least at the secure level, dispatch the combustion generator to supply at least some of the electrical demand and dispatching the VRE power plant to supply at least some of the electrical demand if the electrical power generated by the VRE power plant is not configured for supplying the electrical demand and the combustion generator is operating.

19. The hybrid electrical power generation system of claim 13, wherein the RE power plant comprises a concentrating solar thermal power (CSP) plant.

20. The hybrid electrical power generation system of claim 19, wherein, in response to determining that the CSP plant is not operating, the state of charge of the BESS is at the insecure level and the CSP plant has received instructions to start-up, the controller is configured to:
charge the BESS with the electrical power generated by at least one power plant of the hybrid electrical power generation system; and
defer dispatch of the CSP plant to supply at least some of the electrical demand until the state of charge of the BESS is at the secure level.

21-44. (canceled)
